(19) United States
(12) Patent Application Publication
(10) Pub. No.: US 2021/0399264 A1
(43) Pub. Date: Dec. 23, 2021

(54) DISPLAY DEVICE

(71) Applicants: Sony Corporation, Tokyo (JP); Sony Semiconductor Solutions Corporation, Kanagawa (JP)

(72) Inventors: Daisuke Ueda, Tokyo (JP); Masaaki Sekine, Saitama (JP); Eisuke Negishi, Tokyo (JP)

(21) Appl. No.: 17/279,317

(22) PCT Filed: Sep. 18, 2019
(86) PCT No.: PCT/JP2019/036557

§ 371 Date: Mar. 24, 2021

(30) Foreign Application Priority Data
Oct. 16, 2018 (JP) 2018-194868

(51) Int. Cl. H01L 51/52; H01L 27/32

(52) U.S. Cl. CPC H01L 51/5275; H01L 27/322

(57) ABSTRACT

Provided is a display device including a plurality of light emitting units arranged in a two-dimensional matrix on a substrate. The display device at least includes a first lens unit that is arranged above the plurality of light emitting units and has first microlenses corresponding to each light emitting unit, and a second lens unit that is arranged above the first lens unit and has second microlenses corresponding to each light emitting unit. Alternatively, the display device includes columnar light guide portions that are arranged above the plurality of light emitting units and correspond to each light emitting unit, and a partition wall portion is provided between the light guide portions adjacent to each other.

### TECHNICAL FIELD

The present disclosure relates to a display device.

### BACKGROUND ART

A display element provided with a current-driven light emitting unit, and a display device provided with such a display element are well known. For example, a display element provided with a light emitting unit composed of an organic electroluminescence element is attracting attention as a display element capable of high-luminance light emission by low-voltage direct current drive.

A display device using organic electroluminescence is of a self-luminous type, and also has sufficient responsiveness to a high-definition high-speed video signal. In a display device for wearing on eyewear such as eyeglasses and goggles, for example, in addition to setting a pixel size to about several micrometers to 10 micrometers. it is required to increase the luminance. For example, PTL 1 proposes forming a lens structure on a color filter to improve light extraction efficiency.

### CITATION LIST

### Patent Literature

### [PTL 1]

### JP 2013-149536 A

### SUMMARY

### Technical Problem

When light from a certain pixel leaks to adjacent pixels in a display device, color mixing occurs between the adjacent pixels and the quality of the image is deteriorated. Therefore, in order to increase the luminance, it is required to enable the suppression of color mixing between adjacent pixels while further improving the light extraction efficiency.

An object of the present disclosure is to provide a display device capable of both improving the light extraction efficiency and suppressing color mixing between adjacent pixels.

### Solution to Problem

The display device according to the first aspect of the present disclosure for achieving the above object at least includes:

a plurality of light emitting units arranged in a two-dimensional matrix on a substrate;

a first lens unit that is arranged above the plurality of light emitting units and has first microlenses corresponding to each light emitting unit; and

a second lens unit that is arranged above the first lens unit and has second microlenses corresponding to each light emitting unit.

The display device according to the second aspect of the present disclosure for achieving the above object includes

a plurality of light emitting units arranged in a two-dimensional matrix on a substrate; and

columnar light guide portions that are arranged above the plurality of light emitting units and correspond to each light emitting unit, wherein

a partition wall portion is provided between the light guide portions adjacent to each other.

### BRIEF DESCRIPTION OF DRAWINGS

FIG. 1 is a schematic plan view of a display device according to the first aspect.

FIG. 2 is a schematic partial cross-sectional view of the display device according to the first aspect.

FIGS. 3A and 3B are schematic plan views for explaining the arrangement relationship of various constituent elements constituting a pixel. FIG. 3A shows the arrangement relationship of anode electrodes, and FIG. 3B shows the arrangement relationship of first microlenses.

FIGS. 4A and 4B are schematic plan views for explaining the arrangement relationship of various constituent elements constituting the pixel, following FIG. 3B. FIG. 4A shows the arrangement relationship of color filters, and FIG. 4B shows the arrangement relationship of second microlenses.

FIGS. 5A and 5B are schematic views for explaining light collection by a lens. FIG. 5A is a schematic view of a state of light collection by a single lens. FIG. 5B is a schematic view of a state of light collection by two lenses.

FIG. 6 is a schematic partial cross-sectional view of a display device according to a reference example.

FIGS. 7A and 7B are schematic partial end views for explaining a method for manufacturing the display device according to the first aspect.

FIGS. 8A and 8B are schematic partial end views for explaining the method for manufacturing the display device according to the first aspect, following FIG. 7B.

FIG. 9 is a schematic partial end view for explaining the method for manufacturing the display device according to the first aspect, following FIG. 8B.

FIG. 10 is a schematic partial end view for explaining the method for manufacturing the display device according to the first aspect, following FIG. 9.

FIG. 11 is a schematic partial cross-sectional view of a display device according to a first modification example of the first aspect.

FIG. 12 is a schematic partial cross-sectional view of a display device according to a second modification example of the first aspect.

FIG. 13 is a schematic partial cross-sectional view of a display device according to a third modification example of the first aspect.

FIG. 14 is a schematic cross-sectional view for explaining the relationship between the light emitting region width and the lens width.

FIGS. 15A and 15B are schematic plan views for explaining the arrangement relationship of various constituent elements in the pixels of the modification example. FIG. 15A shows the arrangement relationship of anode electrodes, and

FIG. 15B shows the arrangement relationship of first microlenses.

FIGS. 16A and 16B are schematic plan views for explaining the arrangement relationship of various constituent elements in the pixels of the modification example, following FIG. 15B. FIG. 16A shows the arrangement relationship of color filters, and FIG. 16B shows the arrangement relationship of second microlenses.

FIGS. 17A and 17B are schematic views of a display device according to the second aspect. FIG. 17A shows a schematic plan view of the display device, and FIG. 17B shows a schematic cross-sectional view of the display device.

FIG. 18 is a schematic partial cross-sectional view of the display device according to the second aspect.

FIG. 19 is a schematic view for explaining the reflection of light in a light guide portion.

FIGS. 20A, 20B, and 20C are schematic partial end views for explaining the method for manufacturing the display device according to the second aspect.

FIGS. 21A and 21B are schematic views for explaining the method for manufacturing the display device according to the second aspect. following FIG. 20C. FIG. 21A shows a schematic plan view of a facing substrate, and FIG. 21B shows a schematic cross-sectional view of the facing substrate.

FIGS. 22A and 22B are schematic partial end views for explaining the method for manufacturing a display device according to a second aspect, following FIG. 21B.

FIGS. 23A, 23B, and 23C are schematic partial end views for explaining other process examples.

FIG. 24 is a schematic partial cross-sectional view of a display device according to a first modification example of the second aspect.

FIGS. 25A, 25B, and 25C are schematic partial end views for explaining a method for manufacturing the display device according to the first modification example of the second aspect.

FIGS. 26A, 26B, and 26C are schematic partial end views for explaining the method for manufacturing the display device according to the first modification example of the second aspect, following FIG. 25C.

FIGS. 27A, 27B, and 27C are schematic partial end views for explaining examples of other steps.

FIG. 28 is a schematic partial cross-sectional view of a display device according to a third embodiment.

FIGS. 29A and 29B are schematic partial end views for explaining a method for manufacturing the display device according to the third embodiment.

FIG. 30 is a schematic partial end view for explaining the method for manufacturing the display device according to the third embodiment, following FIG. 29B.

FIG. 31 is a schematic partial end view for explaining the method for manufacturing the display device according to the third embodiment, following FIG. 30.

FIG. 32 is a schematic partial end view for explaining the method for manufacturing the display device according to the third embodiment, following FIG. 31.

FIG. 33 is a schematic partial end view for explaining the method for manufacturing the display device according to the third embodiment, following FIG. 32.

FIG. 34 is a schematic partial end view for explaining the method for manufacturing the display device according to the third embodiment, following FIG. 33.

FIG. 35 is a schematic partial end view for explaining the method for manufacturing the display device according to the third embodiment, following FIG. 34.

FIG. 36 is a schematic partial end view for explaining the method for manufacturing the display device according to the third embodiment, following FIG. 35.

FIG. 37 is a schematic partial end view for explaining the method for manufacturing the display device according to the third embodiment, following FIG. 36.

FIG. 38 is a schematic partial end view for explaining the method for manufacturing the display device according to the third embodiment, following FIG. 37.

FIG. 39 is a schematic partial cross-sectional view of a display device according to a first modification example of the third embodiment.

FIG. 40 is a schematic partial cross-sectional view of a display device according to a second modification example of the third embodiment.

FIG. 41 is a schematic partial cross-sectional view of a display device according to a third modification example of the third embodiment.

FIGS. 42A and 42B are external views of an interchangeable-lens single-lens reflex type digital still camera. FIG. 42A shows a front view, and FIG. 42B shows a rear view.

FIG. 43 is an external view of a head-mounted display.

FIG. 44 is an external view of a see-through head-mounted display.

### DESCRIPTION OF EMBODIMENTS

Hereinafter, the present disclosure will be described based on the embodiments with reference to the drawings. The present disclosure is not limited to the embodiments, and various numerical values and materials in the embodiments are exemplary. In the following description, the same reference numerals will be used for the same elements or elements having the same function, and redundant description will be omitted. The description will be given in the following order.

### 1. Description of Display Devices and General Information Related to the Present Disclosure

### 2. First Embodiment

### 3. Second Embodiment

### 4. Third Embodiment

### 5. Description of Electronic Devices, etc.

### Description of Display Devices and General Information Related to the Present Disclosure

As described above, the display device according to the first aspect of the present disclosure at least includes:

a plurality of light emitting units arranged in a two-dimensional matrix on a substrate;

a first lens unit that is arranged above the plurality of light emitting units and has first microlenses corresponding to each light emitting unit; and

a second lens unit that is arranged above the first lens unit and has second microlenses corresponding to each light emitting unit.

The display device according to the first aspect of the present disclosure may have a configuration in which a color filter is arranged between the first microlens and the second microlens. The microlens may be configured of a well-known colorless and transparent material. The microlens may be formed by a well-known method such as exposure with a gray tone mask, melt flow, and dry etching. The color filter may be configured of a well-known color resist material to which a colorant composed of a desired pigment or dye is added. In some cases, it is also possible to select a material to which no coloring material is added as the color filter and set the corresponding pixel as a white display pixel.

The display device according to the first aspect of the present disclosure including the preferable configurations described above may have a configuration further including a third lens unit that is arranged above the second lens unit and has third microlenses corresponding to each light emitting unit. In this case, a configuration may be used in which the color filter is arranged between the first microlens and the second microlens and between the second microlens and the third microlens.

The display device according to the first aspect of the present disclosure including the various preferable configurations described above may have a configuration in which the refractive index of the material constituting the first microlens is larger than the refractive index of the material constituting the second microlens. In this case, a configuration may be used in which a color filter is arranged between the first microlens and the second microlens, and the refractive index of the optical material constituting the color filter is lower than the refractive index of the optical material constituting the first microlens and equal to or higher than the refractive index of the optical material constituting the second microlens. Further. a configuration may be used in which the first microlens is formed of an inorganic material, and the second microlens is formed of an organic material. The refractive index of the constituent materials used in the present disclosure can be determined by measuring with, for example, an ellipsometer.

As described above, the display device according to the second aspect of the present disclosure includes

a plurality of light emitting units arranged in a two-dimensional matrix on a substrate; and

columnar light guide portions that are arranged above the plurality of light emitting units and correspond to each light emitting unit, wherein

a partition wall portion is provided between the light guide portions adjacent to each other.

The display device according to the second aspect of the present disclosure may have a configuration in which a boundary surface between the partition wall portion and the light guide portion forms a light reflecting surface.

The display device according to the second aspect of the present disclosure including the preferable configurations described above may have a configuration in which the light guide portion is formed of a dielectric material. In this case, a configuration may be used in which the light guide portion is formed of an organic material. Examples of the organic material include an acrylic resin material, an organosilicon resin such as polysiloxane, and the like.

The display device according to the second aspect of the present disclosure including the preferable configurations described above may have a configuration in which the partition wall portion is provided so as to have a refractive index smaller than that of the light guide portion. In this case, a configuration may be used in which the partition wall portion is formed as a space. The space may be in a state where the pressure is kept lower than the standard atmospheric pressure as a practical vacuum state, or may be in a state of being filled with a gas such as the atmosphere or nitrogen. Alternatively, a configuration may also be used in which the partition wall portion is formed of a dielectric material.

Alternatively, the display device according to the second aspect of the present disclosure including the various preferable configurations described above may have a configuration in which the partition wall portion is formed of a metal material. As the metal material, it is preferable to select a metal material having a high reflectance of visible light, and examples thereof can include aluminum (Al), gold (Au), silver (Ag), chromium (Cr), nickel (Ni), or an alloy including these.

The display device according to the second aspect of the present disclosure including the various preferable configurations described above may have a configuration in which a boundary surface between the partition wall portion and the light guide portion extends in the normal direction of a virtual plane including the plurality of light emitting units. Alternatively, a configuration may also be used in which the boundary surface between the partition wall portion and the light guide portion extends so as to form a predetermined angle with respect to the normal direction of the virtual plane including the plurality of light emitting units.

The display device according to the second aspect of the present disclosure including the various preferable configurations described above may have a configuration which is provided with a transparent substrate arranged so as to face the substrate, and in which, the substrate is provided with a joint portion arranged so as to surround the region of the plurality of light emitting units arranged in a two-dimensional matrix, and the substrate and the transparent substrate are joined through the joint portion.

For example, the substrate and the transparent substrate can be irradiated with plasma to activate the surface etc. of the joint portion in vacuum, and then these can be joined in vacuum. In this case, from the viewpoint of adhesion, it is preferable to form a thin film made of an inorganic material such as a metal or silicon on the joint surface. It is preferable that the height of the joint portion is formed to be the same as that of the light guide portion. In general, by sharing the process of forming the joint portion and the process of forming the light guide portion, the joint portion and the light guide portion can be formed to the same height.

The display device according to the second aspect of the present disclosure including the various preferable configurations described above may have a configuration in which the light guide portion at least includes a first microlens located above the light emitting unit and a second microlens located above the first microlens. In this case, a configuration may be used in which the partition wall portion is embedded in a packing layer provided between the first microlens and the second microlens, and is provided so that the refractive index thereof is smaller than that of the packing layer. Alternatively, a configuration may be used in which a color filter is arranged between the light emitting unit and the first microlens, between the first microlens and the second microlens, or above the second microlens.

In the display device according to the present disclosure including the various preferable configurations described above, examples of the light emitting unit include an organic electroluminescence light emitting unit, an LED light emitting unit, and a semiconductor laser light emitting unit. These light emitting units can be configured using well-known materials and methods. From the viewpoint of configuring a flat display device, it is preferable that the light emitting unit is composed of an organic electroluminescence light emitting unit.

The organic electroluminescence light emitting unit is preferably of a so-called top-surface light emitting type. The organic electroluminescence light emitting unit can be composed of an anode electrode, a hole transport layer, a light emitting layer, an electron transport layer, a cathode electrode, and the like.

When the display device is a color display, the display device can be configured by combining a white light emitting unit and a color filter. In this configuration, an organic layer including a hole transport layer, a light emitting layer, an electron transport layer, and the like can be shared among a plurality of pixels. Therefore, it is not necessary to individually paint the organic layer for each pixel. Alternatively, a configuration may be used in which a red light emitting organic layer, a green light emitting organic layer, and a blue light emitting organic layer are individually painted according to the pixels. In this configuration, the finer the pixel pitch, the more difficult it is to paint individually. Therefore, in a display device having a pixel pitch in the order of micrometers, it is preferable to have a configuration in which a white light emitting unit and a color filter are combined.

In the organic electroluminescence light emitting unit that emits white light, for example. the organic layer may be embodied to have a laminated structure including a red light emitting layer, a green light emitting layer, and a blue light emitting layer. Alternatively, the organic layer may be embodied to have a laminated structure including a blue light emitting layer that emits blue light and a yellow light emitting layer that emits yellow light, or a laminated structure that includes a blue light emitting layer that emits blue light and an orange light emitting layer that emits orange light. These layers will emit white light as a whole. The material constituting the organic layer is not particularly limited, and a well-known material can be used.

Examples of the material constituting the anode electrode of the organic electroluminescence light emitting unit include metals such as platinum (Pt), gold (Au), silver (Ag), chromium (Cr), tungsten (W), nickel (Ni), aluminum (Al), copper (Cu), iron (Fe), cobalt (Co), tantalum (Ta), etc. or alloys, and transparent conductive materials such as such as indium-tin oxide (ITO, inclusive of Sn-doped In₂O₃, crystalline ITO and amorphous ITO) and indium-zinc oxide (IZO).

As a material constituting the cathode electrode of the organic electroluminescence light emitting unit, a conductive material is preferable so that emitted light can be transmitted and electrons can be efficiently injected into the organic layer. For example, metals or alloys such as aluminum (Al), silver (Ag), magnesium (Mg), calcium (Ca), sodium (Na), strontium (Sr), Mg—Ag alloy, Mg—Ca alloy, Al—Li alloy, etc. can be mentioned.

A drive unit for driving the light emitting units is provided below the substrate on which the light emitting units are arranged, but this configuration is not limiting. A drive circuit may be configured of, for example, a transistor (specifically, for example, MOSFET) formed on a silicon semiconductor substrate constituting the substrate, or a thin film transistor (TFT) provided on various substrates constituting the substrate. An embodiment is possible in which the transistor constituting the drive circuit and the light emitting units are connected to each other via contact holes (contact plugs) formed in the substrate or the like. The drive circuit may have a well-known circuit configuration.

The arrangement of pixels is not particularly limited as long as the implementation of the display device of the present disclosure is not hindered. Examples of the pixel array include a square array, a delta array, and a striped array.

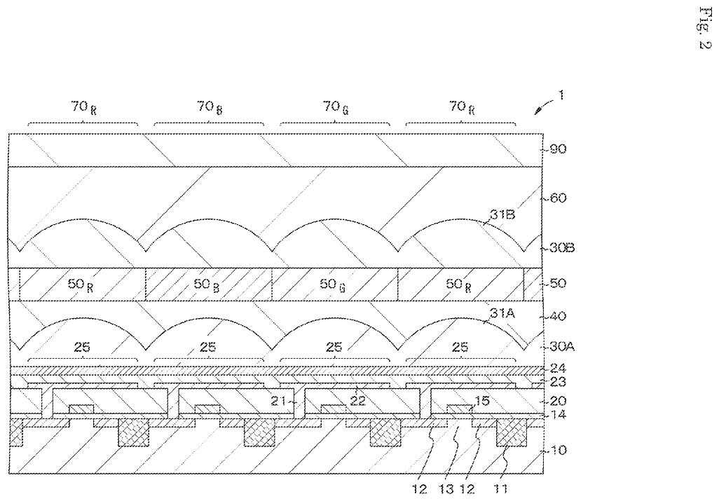

The various requirements in this specification are satisfied not only when they are mathematically strictly satisfied but also when they are substantially satisfied. The presence of various design or manufacturing variations is acceptable. In addition, each drawing used in the following description is a schematic one and does not show actual dimensions or the ratio thereof. For example, FIG. 2, which will be described hereinbelow, shows the cross-sectional structure of the display device, but does not show the proportions such as width, height, and thickness.

### First Embodiment

The first embodiment relates to a display device according to the first aspect of the present disclosure.

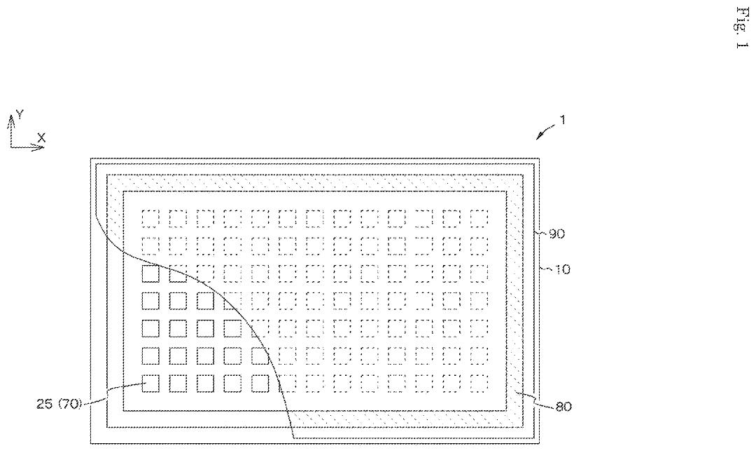

FIG. 1 is a conceptual diagram of a display device according to the first embodiment. FIG. 2 is a schematic partial cross-sectional view of the display device according to the first aspect.

As shown in FIG. 1, a display device 1 includes a plurality of light emitting units 25 arranged in a two-dimensional matrix on a substrate 10. The light emitting units 25 are arranged so as to correspond to each pixel 70 of the display device 1. The light emitting unit 25 is configured of an organic electroluminescence element. The configuration of the light emitting unit 25 will be described in detail hereinbelow. The display device 1 includes a transparent substrate 90 arranged so as to face the substrate 10. Reference numeral 80 indicates a joint portion between the substrate 10 and the transparent substrate 90, the joint portion being provided so as to surround a display region.

As shown in FIG. 2, the display device 1 includes a first lens unit 30A that is arranged above the plurality of light emitting units 25 and includes first microlenses 31A corresponding to each light emitting unit 25, and a second lens unit 30B that is arranged above the first lens unit 30A and includes second microlenses 31B corresponding to each light emitting unit 25. The first microlens 31A and the second microlens 31B are formed as a convex lens having a convex shape on the light outgoing side. In the figure, the microlens is configured to have a convex lens shape on the light outgoing side, but this is just an example, and as shown in the present example, it is sufficient if the lens can have a refraction function, and a shape such that the light emitting unit side has a convex shape is sufficient. Therefore, the shape of the microlens is not limited to the shape shown in the figure.

A color filter 50 is arranged between the first microlenses 31A and the second microlenses 31B. More specifically, a flattening film 40 is provided on the first microlenses 31A, and a color filter 50 is arranged thereon. The second microlenses 31B are arranged on the color filter 50. A pixel 70 is configured of the light emitting unit 25 and the first microlens 31A, the color filter 50, and the second microlens 31B corresponding thereto. In FIG. 2, a red color filter, a green color filter, and a blue color filter are represented by reference numerals 50_{R}, reference numeral 50_{G}, and reference numeral 50B, respectively. Similarly, a red display pixel, a green display pixel, and a blue display pixel are represented by reference numerals 70_{R}, 70_{G}, and 70_{B}. The same applies to other drawings described hereinbelow. In some cases, it is also possible to select a material to which no coloring material is added as the color filter and set the corresponding pixel as a white display pixel.

The relationship between the refractive indexes of the materials constituting the first microlens 31A, the second microlens 31B, and the color filter 50 will be described. The refractive index of the material forming the first microlens 31A is larger than the refractive index of the material forming the second microlens 31B. Further, the refractive index of the optical material forming the color filter 50 is smaller than the refractive index of the optical material forming the first microlens 31A and equal to or higher than the refractive index of the optical material forming the second microlens 31B.

The first microlens 31A is formed of an inorganic material, and the second microlens 31B is formed of an organic material. Specifically, the first microlens 31A is formed of silicon nitride (refractive index is about 1.8), and the color filter 50 and the flattening film 40 are formed of an acrylic resin material (refractive index is about 1.4 to 1.5). The second microlens 31B is formed by selecting an acrylic resin material having a refractive index smaller than or the same as that of the color filter 50.

Reference numeral 60 stands for a sealing resin layer provided between the second microlenses 31B and the transparent substrate 90. A material constituting the sealing resin layer 60 can be exemplified by a thermosetting adhesive such as an acrylic adhesive, an epoxy adhesive, an urethane adhesive, a silicone adhesive, and a cyanoacrylate adhesive, and an ultraviolet-curable adhesive. It is desirable that the refractive index of the sealing resin layer 60 be smaller than the refractive index of the optical material constituting the second microlens 31B.

Next, the light emitting units 25 and a drive circuit for driving the light emitting units 25 will be described.

The drive circuit that drives the light emitting units 25 is configured of MOSFETs etc. formed on a silicon semiconductor substrate corresponding to the substrate 10. A transistor composed of the MOSFET is configured of a gate insulating layer 14 formed on the substrate 10, a gate electrode 15 formed on the gate insulating layer 14, source/drain regions 12 formed in the substrate 10, a channel forming region 13 formed between the source/drain regions 12, and an element separation region 11 surrounding the channel forming region 13 and the source/drain regions 12. Reference numeral 20 stands for a flattening film that covers the entire surface including the top of the gate electrode 15.

Anode electrodes 22 arranged correspondingly to each of the light emitting units 25 are formed on the flattening film 20. The anode electrode 22 and the transistor are electrically connected via a contact plug 21 provided in the flattening film 20.

An organic layer 23 that emits white light is formed on the entire surface including the top of the anode electrodes 22. The organic layer 23 has a laminated structure of a red light emitting layer, a green light emitting layer, and a blue light emitting layer. Although the organic layer 23 is formed by laminating a plurality of material layers, it is represented by one layer in the figure. A cathode electrode 24, which is arranged as a common electrode for the light emitting units 25, is formed on the organic layer 23. For example, a ground potential is supplied to the cathode electrode 24. In some cases, a configuration may be used in which the red light emitting organic layer, the green light emitting organic layer, and the blue light emitting organic layer are individually painted according to the pixels.

When a voltage is applied between the anode electrode 22 and the cathode electrode 24, the portion of the organic layer 23 located on the anode electrode 22 emits light. As described above, the light emitting unit 25 is configured of an organic electroluminescence element.

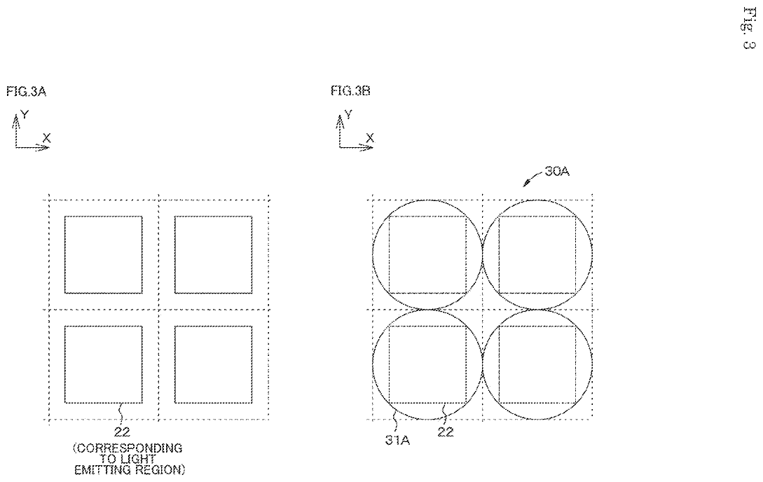

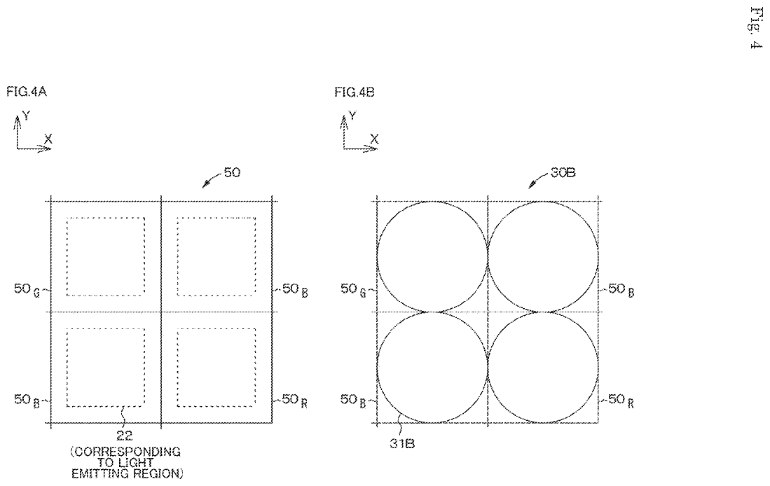

In the display device 1, the pixels are, for example, squarely arranged. FIGS. 3A and 3B are schematic plan views for explaining the arrangement relationship of various constituent elements constituting the pixel. FIG. 3A shows the arrangement relationship of the anode electrodes, and FIG. 3B shows the arrangement relationship of the first microlenses. FIGS. 4A and 4B are schematic plan views for explaining the arrangement relationship of various constituent elements constituting the pixel, following FIG. 3B. FIG. 4A shows the arrangement relationship of the color filters, and FIG. 4B shows the arrangement relationship of the second microlenses.

The configuration of the display device 1 has been described in detail above.

Subsequently, the effect of forming the second microlenses 31B in addition to the first microlenses 31A will be qualitatively explained.

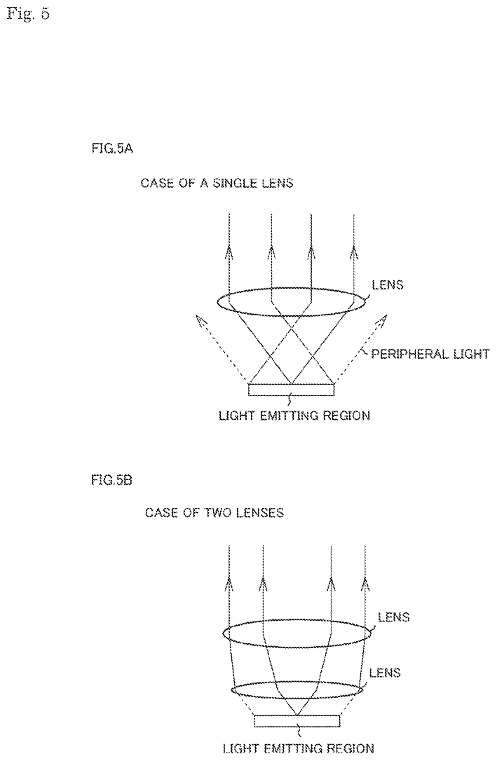

FIGS. 5A and 5B are schematic views for explaining how light is collected by a lens. FIG. 5A is a schematic view showing how light is collected by a single lens. FIG. 5B is a schematic view showing how light is collected by two lenses.

The light emitting region of the light emitting unit 25 has a surface shape rather than a point shape. As shown in FIG. 5A, in the case of a single lens, the degree to which the light from the peripheral portion of the light emitting region spreads outside the corresponding lens is large. Therefore, there is a limit in improving the light extraction efficiency, and the suppression of color mixing between adjacent pixels is also insufficient.

With a two-lens configuration as shown in FIG. 5B, the light from the peripheral portion of the light emitting region can be sufficiently guided to the corresponding lens. Therefore, this configuration is superior to that in FIG. 5A in terms of light extraction efficiency and suppression of color mixing. Further, as is clear from FIG. 5B, qualitatively, it is preferable to bring the front lens of the two lenses closer to the light emitting region.

As described above, in the display device 1, the first microlenses 31A corresponding to each light emitting unit 25 and the second microlenses 31B arranged above the first lens unit 30A are arranged. A color filter 50 is arranged between the first microlenses 31A and the second microlenses 31B. With this configuration, the first microlenses 31A are arranged close to the light emitting units 25.

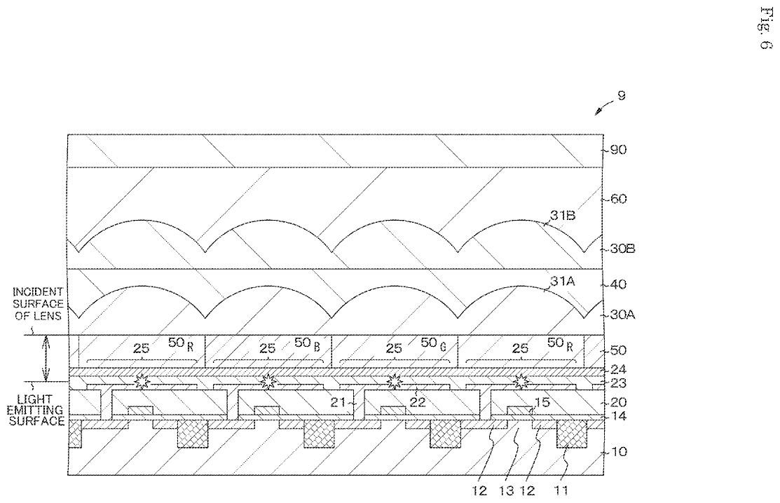

As a configuration of the display device, it is conceivable to arrange the color filter 50 in a lower layer, but such a configuration is disadvantageous in terms of arranging the first microlenses 31A close to the light emitting units 25. This will be explained with reference to FIG. 6.

FIG. 6 is a schematic partial cross-sectional view of a display device according to a reference example.

A display device 9 shown in FIG. 6 has a configuration in which a color filter 50 is formed adjacent to the light emitting units 25, and the first microlenses 31A and the second microlenses 31B are arranged above the color filter 50. In this case, since the color filter 50 is located between the first microlenses 31A and the light emitting units 25, the distance between the light incident surface and the light emitting surface of the first microlens 31A is larger than that in the configuration shown in FIG. 2.

Meanwhile, in the display device 1 shown in FIG. 2, the first microlenses 31A are arranged close to the light emitting units 25. Therefore, since the light-collecting power of the first microlens 31A is sufficiently exhibited, this is advantageous in terms of improving the light extraction efficiency and suppressing color mixing between adjacent pixels.

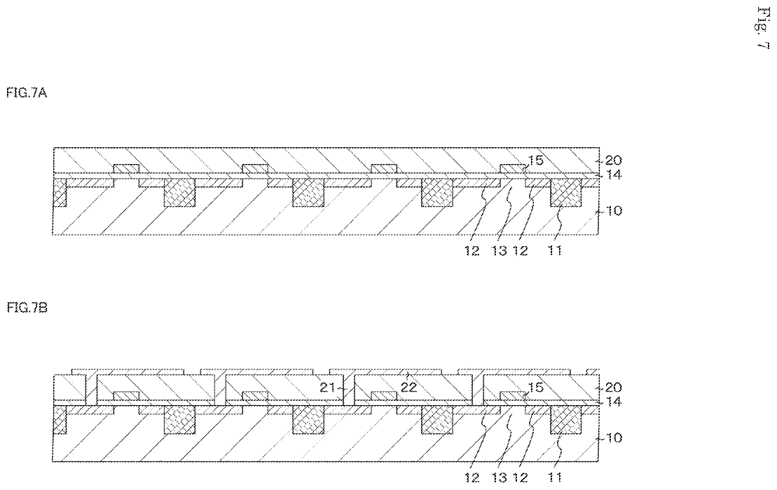

The outline of the method for manufacturing the display device 1 will be described hereinbelow with reference to FIGS. 7A, 7B, 8A, 8B, 9, and 10 which are schematic partial end views of the substrate and the like.

[Step-100]

First, MOSFETs or the like that serve as a drive circuit for the light emitting units 25 are formed on the substrate 10, and a flattening film 20 is formed on the MOSFETs (see FIG. 7A).

[Step-110]

Next, openings are formed in the flattening film 20 at positions where the contact plugs 21 are to be arranged, and a conductive material layer constituting the anode electrodes 22 is formed on the entire surface including the openings. After that, the conductive material layer is patterned to form the anode electrodes 22 on the flattening film 20 (see FIG. 7B).

[Step-120]

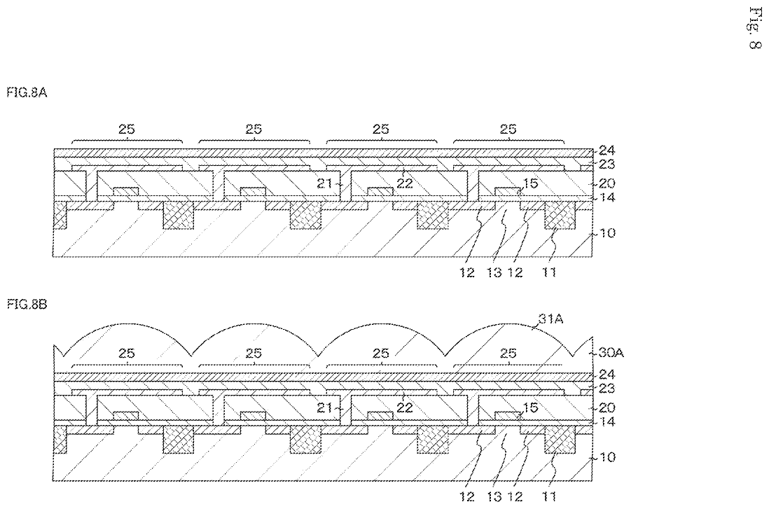

Next, the organic layer 23 is formed on the anode electrodes 22 and the flattening film 20 by, for example, a PVD method such as a vacuum deposition method or a sputtering method, a coating method such as a spin coating method or a die coating method, or the like. After that, the cathode electrode 24 is formed on the entire surface based on, for example, a vacuum vapor deposition method (see FIG. 8A).

[Step-130]

Next, the first lens unit 30A provided with first microlenses 31A corresponding to each light emitting unit 25 is formed on the entire surface (see FIG. 8B).

[Step-140]

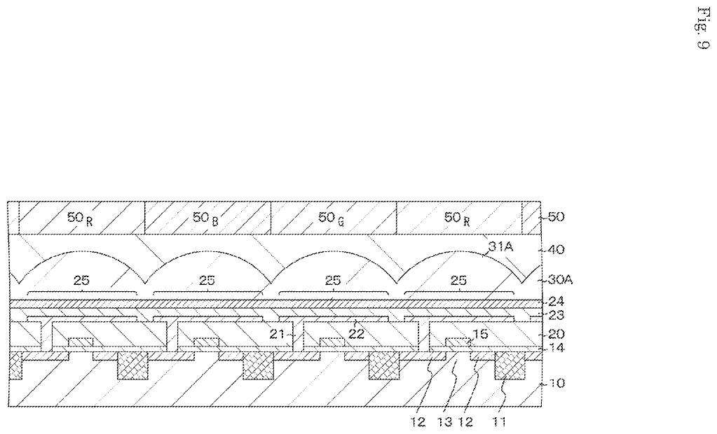

After that, the flattening film 40 is formed on the entire surface. Next, a color filter 50 is formed on the flattening film by a well-known method (see FIG. 9).

[Step-150]

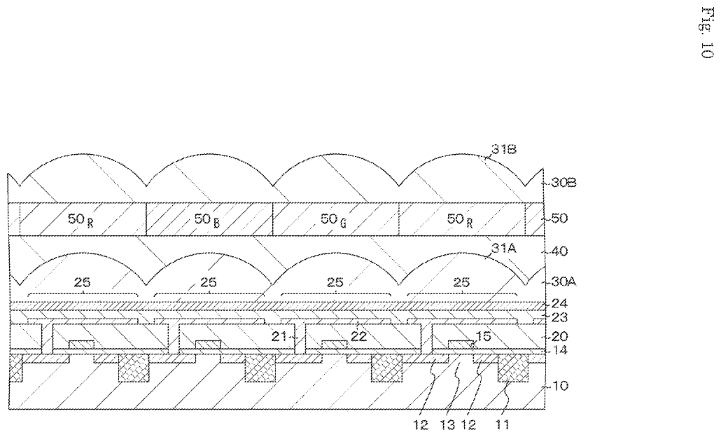

After that, a second lens unit 30B provided with second microlenses 31B corresponding to each light emitting unit 25 is formed on the entire surface (see FIG. 10). Next, the transparent substrate 90 is attached via the sealing resin layer 60 made of, for example, an acrylic adhesive. In this way, the display device 1 shown in FIG. 2 can be obtained.

The outline of the method for manufacturing the display device 1 has been explained above.

Various modifications are possible for the first embodiment. Hereinafter, a modification example will be described with reference to the drawings.

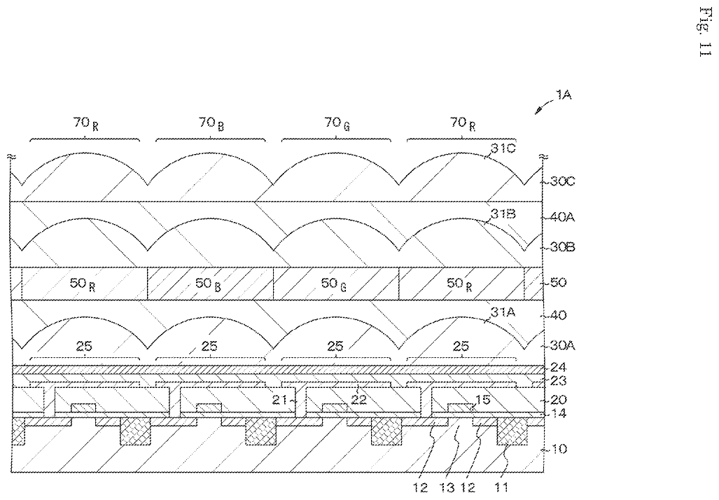

FIG. 11 is a schematic partial cross-sectional view of the display device according to the first modification example of the first aspect.

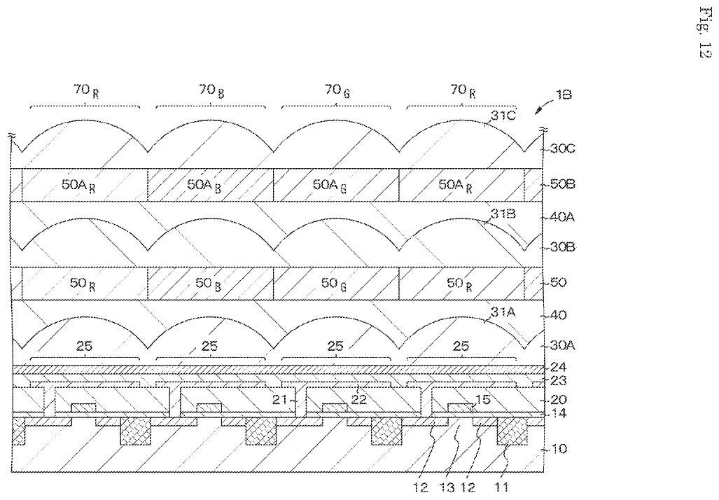

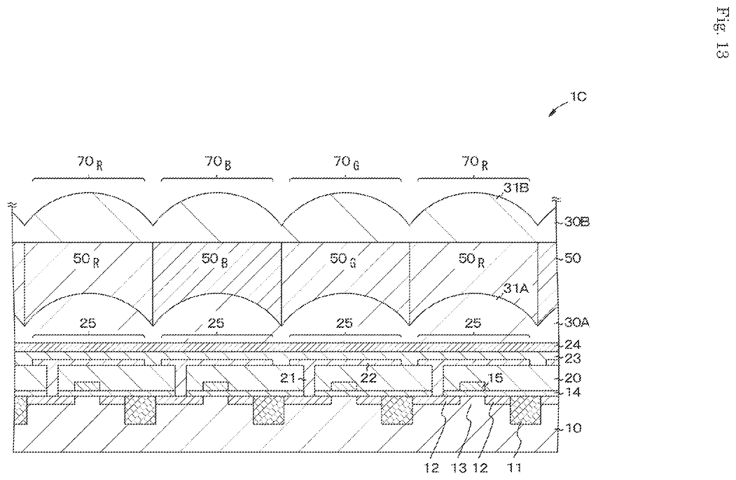

The display device 1A according to the first modification example has a configuration further including a third lens unit that is arranged above the second lens unit and is provided with third microlenses corresponding to each light emitting unit 25. More specifically, this is the configuration obtained by further arranging a third lens unit 30C having third microlenses 31C above the second lens unit 30B of the display device 1 shown in FIG. 2. For convenience of illustration, the sealing resin layer 60 and the transparent substrate 90 are not shown in FIG. 11. The same applies to FIGS. 12 and 13 described hereinbelow.

FIG. 12 is a schematic partial cross-sectional view of a display device according to a second modification example of the first aspect.

The display device 1B according to the second modification example has a configuration in which a color filter is arranged between the first microlens and the second microlens and between the second microlens and the third microlens. More specifically, this is the configuration obtained by further arranging a color filter 50A between the second microlens 31B and the third microlens 31C of the display device 1B shown in FIG. 11.

FIG. 13 is a schematic partial cross-sectional view of the display device according to the third modification example of the first aspect.

The display device 1C according to the third modification example has a configuration in which the flattening film 40 is omitted and the color filter 50 is formed in the display device 1 shown in FIG. 2. This configuration can further improve a chromaticity viewing angle characteristic.

The various modification examples in the first aspect have been described above.

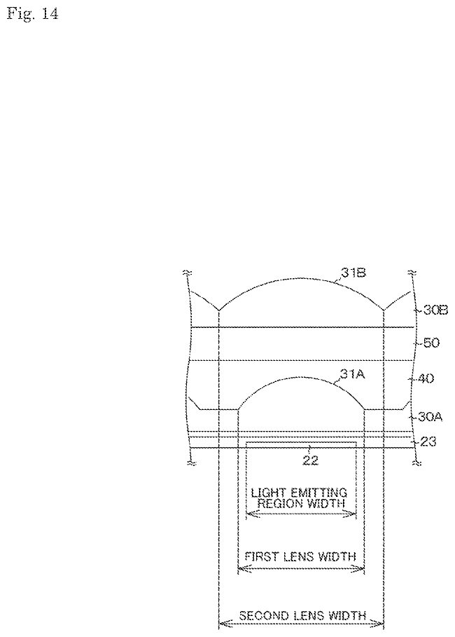

In the various drawings described above, the widths of the microlenses are described as being substantially the same, but the widths of the microlenses do not necessarily have to be the same. FIG. 14 is a schematic cross-sectional view for explaining the relationship between the light emitting region width and the lens width. In order to efficiently improve the luminance, it is preferable that the width of the first microlens be equal to or greater than the width of the light emitting region, and the width of the second microlens be equal to or greater than the width of the first microlens.

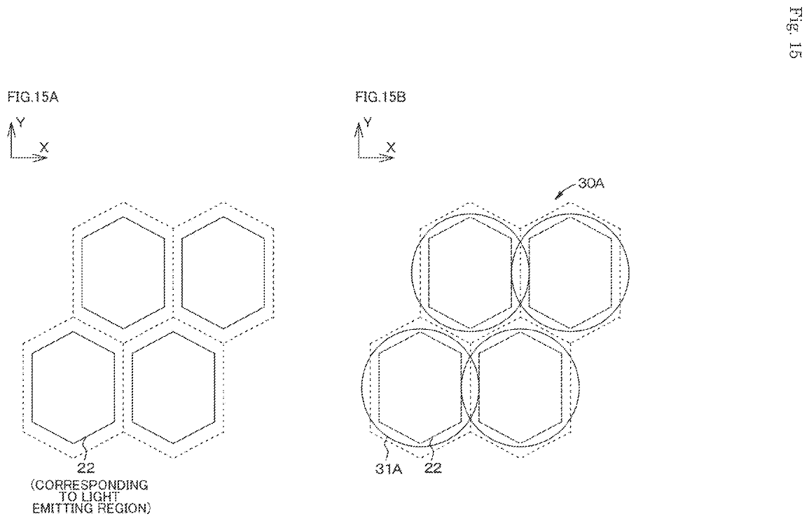

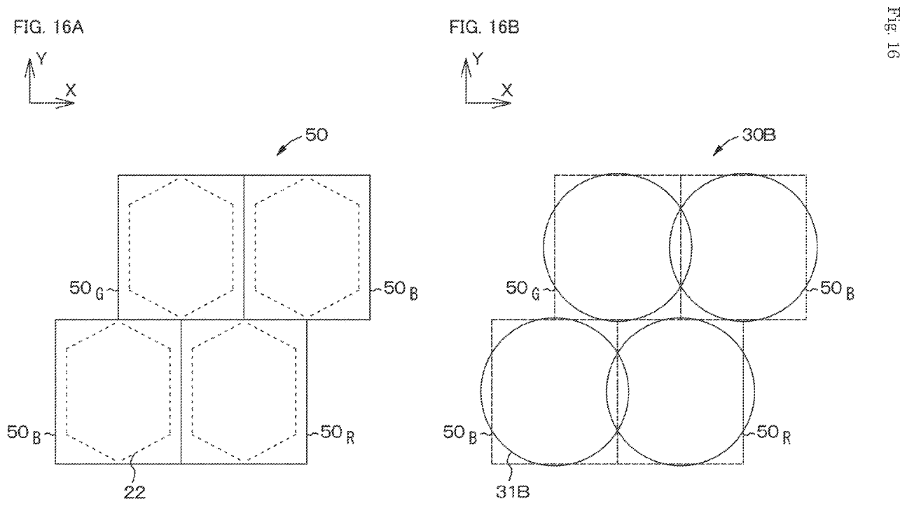

Further, in the display device 1, the pixels may be arranged in an array other than, for example, a square array. As an example, the arrangement of the pixels of the modification example in a delta array is shown in the figure. FIGS. 15A and 15B are schematic plan views for explaining the arrangement relationship of various constituent elements in the pixels of the modification example. FIG. 15A shows the arrangement relationship of the anode electrodes, and FIG. 15B shows the arrangement relationship of the first microlenses. FIGS. 16A and 16B are schematic plan views for explaining the arrangement relationship of various components in the pixels of the modification example, following FIG. 15B. FIG. 16A shows the arrangement relationship of the color filters, and FIG. 16B shows the arrangement relationship of the second microlenses.

### Second Embodiment

The second embodiment relates to a display device according to the second aspect of the present disclosure.

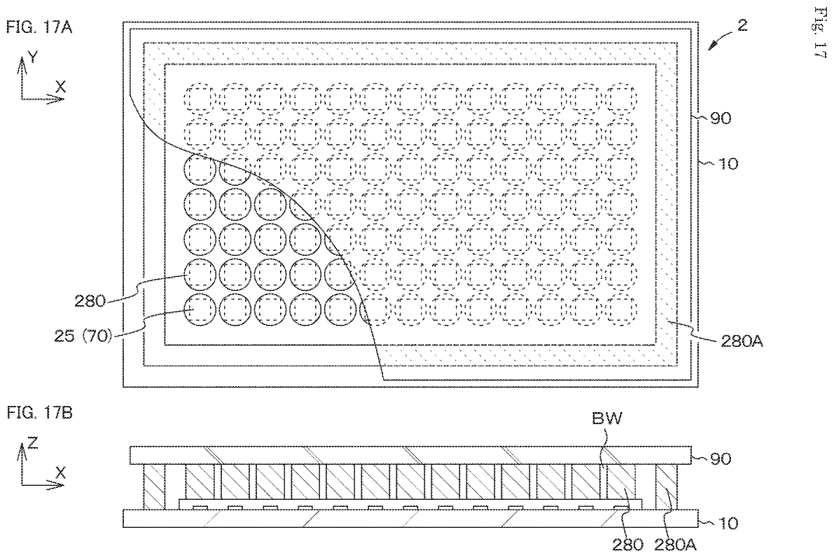

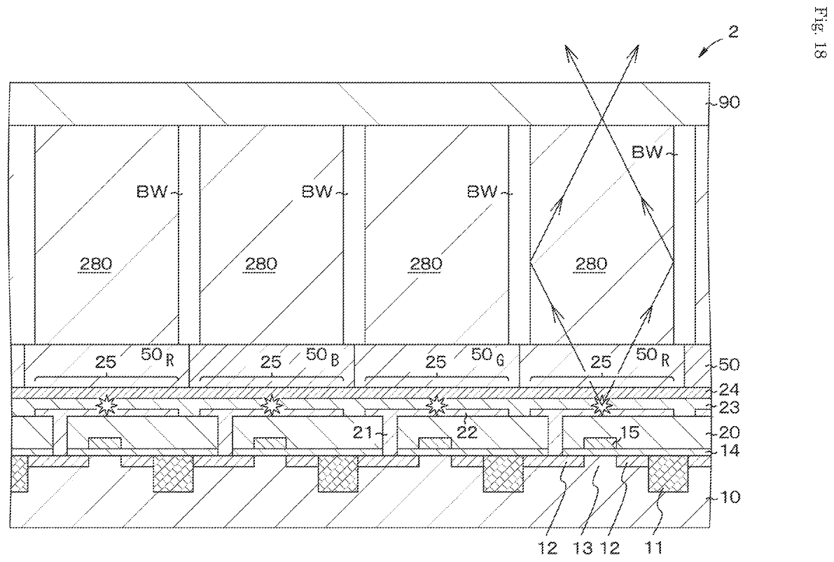

FIGS. 17A and 17B are schematic views of the display device according to the second aspect. FIG. 17A shows a schematic plan view of the display device, and FIG. 17B shows a schematic cross-sectional view of the display device. FIG. 18 is a schematic partial cross-sectional view of the display device according to the second aspect.

As shown in FIG. 17, a display device 2 includes a plurality of light emitting units 25 arranged in a two-dimensional matrix on the substrate 10. The light emitting units 25 are arranged so as to correspond to each pixel 70 of the display device 2. The display device 2 includes a transparent substrate 90 arranged so as to face the substrate 10. Reference numeral 280A indicates a joint portion between the substrate 10 and the transparent substrate 90 provided so as to surround the display region.

As shown in FIGS. 17 and 18. the display device 2 includes columnar light guide portions 280 that are arranged above the plurality of light emitting units 25 and correspond to each light emitting unit 25. A partition wall portion BW is provided between the light guide portions 280 adjacent to each other. Similar to the display device 9 of the reference example shown in FIG. 6 referred to in the first embodiment, the color filter 50 is formed adjacent to the light emitting unit 25, and the light guide portion 280 is arranged on the color filter 50. The configuration of the substrate 10 to the color filter 50 is the same as the configuration described in the first embodiment, and thus the description thereof will be omitted.

In the display device 2, the partition wall portion BW is provided so that the refractive index thereof is smaller than that of the light guide portion 280, and the boundary surface between the partition wall portion BW and the light guide portion 280 forms a light reflecting surface. That is, when the light from the light emitting unit 25 is incident on the boundary surface from the light guide portion 280 beyond the critical angle, the light is totally reflected and guided to the observer side. Therefore, it is possible to improve the light extraction efficiency and suppress the color mixing between adjacent pixels.

In the display device 2, the partition wall portion BW is formed as a space. The light guide portion 280 is formed of a dielectric material. More specifically, the light guide portion 280 is formed of an organic material such as an acrylic resin material or an organic silicone resin material such as polysiloxane. The boundary surface between the partition wall portion BW and the light guide portion 280 is formed so as to extend in the normal direction of the virtual plane including the plurality of light emitting units 25. In some cases, the boundary surface between the partition wall portion BW and the light guide portion 280 may be formed so as to extend at a predetermined angle with respect to the normal direction of the virtual plane including the plurality of light emitting units 25.

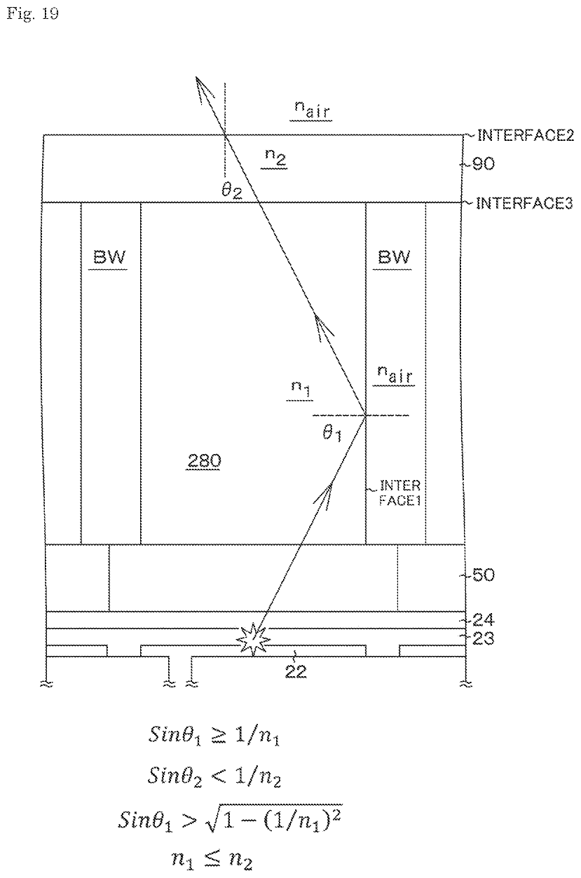

FIG. 19 is a schematic view for explaining the reflection of light in the light guide portion.

Both the refractive index of the partition wall portion BW and the refractive index of the space are represented by the symbol nₐᵢᵣ, the refractive index of the light guide portion 280 is represented by the symbol n₁, and the refractive index of the transparent substrate 90 is represented by the symbol n₂. Here, it is assumed that the refractive index nₐᵢᵣ=1. When the angle of incidence of light on the boundary surface (interface 1) is represented by the symbol θ₁, where Sin(θ₁)≥1/n₁, the light is totally reflected at the boundary surface, so that the light extraction efficiency is improved. Further, the condition that light can be taken out to the outside at an interface 2 between the transparent substrate 90 and the outside is Sin(θ₂)<1/n₂ in FIG. 19.

Snell's law at an interface 3 is expressed as

Sin(π/2−θ₁)/Sin(θ₂)=n₂/n₁.

When this formula is transformed,

Sin(θ₂)=(n₁/n₂)×(1−Sin²(θ₁))^{1/2}

is obtained, and by substituting this into the above-mentioned Sin(θ₂)<1/n₂ and rearranging,

Sin(θ₁)>(1−(1/n₁)²)^{1/2}

is obtained. Therefore, if 1/n₁=(1−(1/n₁)²)^{1/2} is set, the amount of light that can be extracted is maximized. Accordingly, it is preferable to set a value of n₁=2^{1/2}.

As described above, the substrate 10 of the display device 2 is provided with a joint portion 280A arranged so as to surround the region of the plurality of light emitting units 25 arranged in a two-dimensional matrix. The height of the joint portion 280A is formed to be the same as that of the light guide portion 280. More specifically, the joint portion 280A and the light guide portion 280 are formed by patterning the same material layer. As described below, the display device 2 also has an advantage that so-called narrowing of the frame is easy.

When the substrate 10 and the transparent substrate 90 were sealed with frit glass or the like, there was a limit to narrowing the frame, for example, because melting of the frit glass has an effect on the organic layer 23, and it is difficult to apply the frit glass in a narrow width. Further, even if the joining is performed at room temperature under low pressure conditions such as vacuum, if this is performed without the light guide portion 280, the internal pressure is low, so that the substrate 10 and the transparent substrate 90 are deformed. Moreover, since the configuration is hollow, the light extraction efficiency is reduced.

By contrast, in the display device 2, the distance between the substrate 10 and the transparent substrate 90 is maintained by a large number of light guide portions 280 even if the joining is performed at room temperature under low pressure conditions such as vacuum. Therefore, it is possible to narrow the frame while preventing the substrate 10 and the transparent substrate 90 from being deformed.

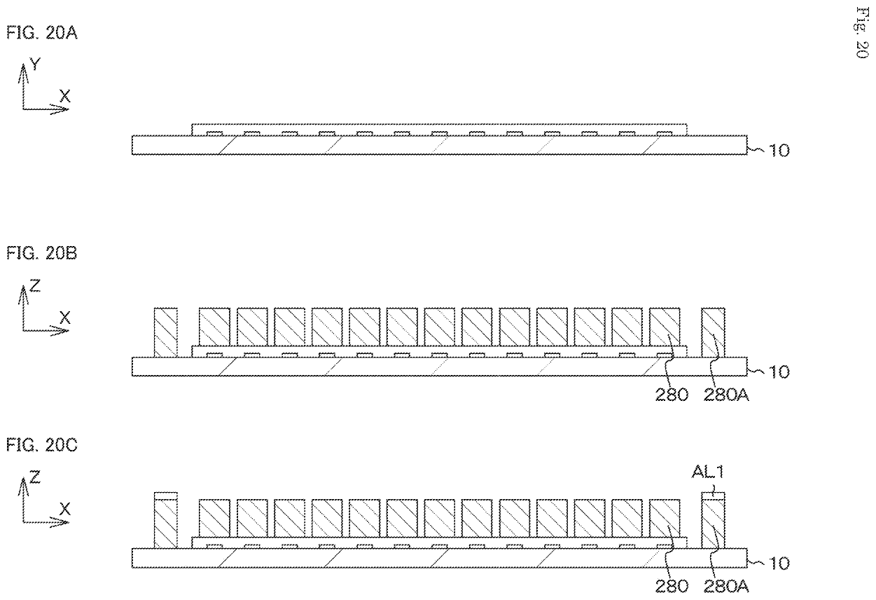

The outline of the method for manufacturing the display device 2 will be described hereinbelow with reference to FIGS. 20A, 20B, 20C, 21A, 21B, 22A, and 22B which are schematic partial end views of the substrate and the like.

[Step-200]

First, the drive circuit of the light emitting units 25, the light emitting units 25, the color filter 50, and the like are formed on the substrate 10 (see FIG. 20A). For convenience, the transistors that form the drive circuit, the light emitting units 25, the color filter 50, and the like are shown in a simple manner.

[Step-210]

Next, the same material layer constituting the joint portion 280A and the light guide portions 280 is formed on the entire surface, and then the joint portion 280A and the light guide portions 280 are formed by a well-known patterning technique (see FIG. 20B).

[Step-220]

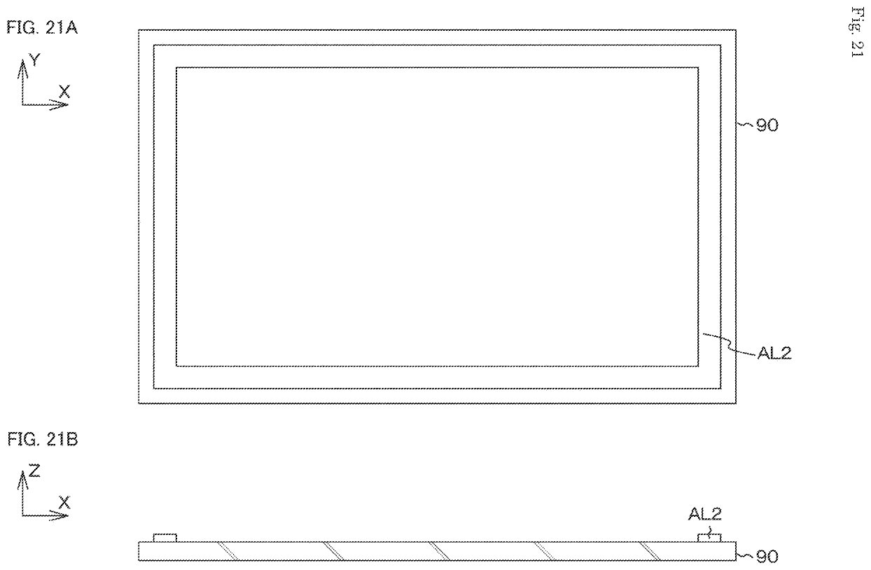

After that, in order to improve the adhesion at room temperature, an inorganic film AL1 is formed on the upper surface of the joint portion 280A provided on the substrate 10 (see FIG. 20C), and an inorganic film AL2 is formed on the portion of the transparent substrate 90 corresponding to the joint portion 280A (see FIGS. 21A and 21B). The inorganic film can be formed as a thin film of silicon (Si), titanium (Ti), copper (Cu), or the like.

[Step-230]

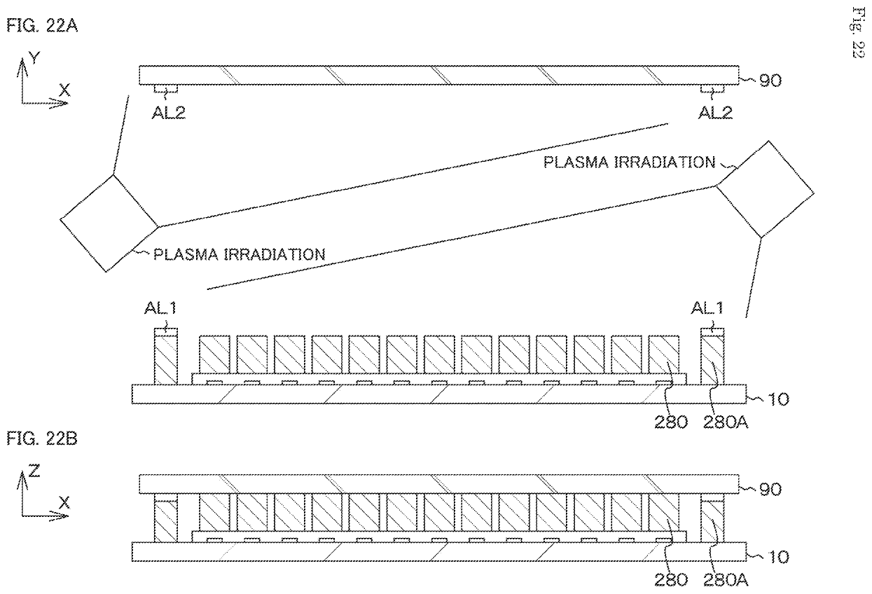

Next, the inorganic film AL1 of the substrate 10 and the inorganic film AL2 of the transparent substrate 90 are activated. For example, they can be activated by irradiating with Ar plasma (see FIG. 22A).

[Step-240]

After that, the substrate 10 and the transparent substrate 90 are set to face each other, and joined at normal temperature in vacuum (see FIG. 22B). As a result, the display device 2 can be obtained. Since it is sufficient that the space of the partition wall portion BW is under low-pressure conditions such as vacuum and the inorganic film is formed with a sufficiently small thickness, the upper surface of the light guide portions 280 and the transparent substrate 90 are in close contact with each other.

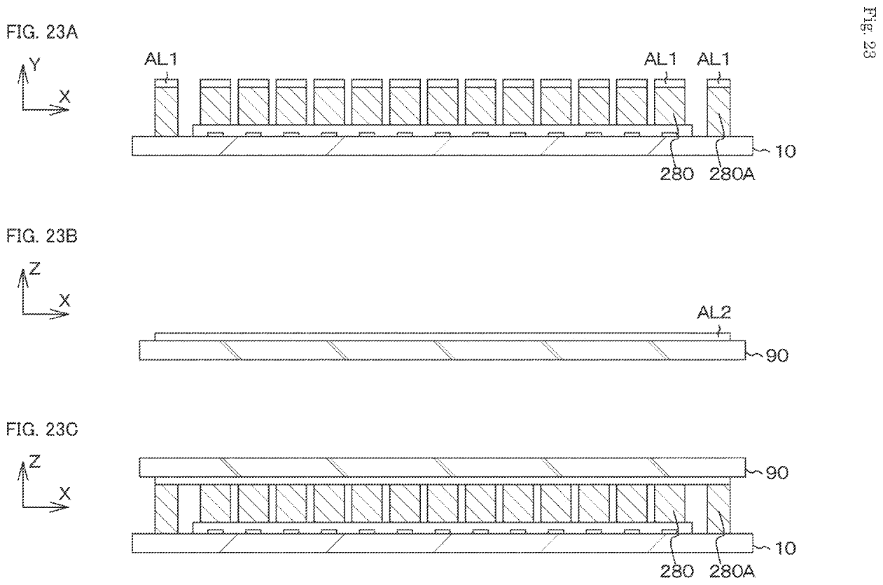

In the above-mentioned Step-220, the adhesion layer was formed in a limited manner. Meanwhile, for example, by performing oblique vapor deposition, it is possible to obtain a configuration in which an inorganic film is formed not only on the upper surface of the joint portion but also on the upper surface of the light guide portions. Hereinafter, an outline of a modification example of the method for manufacturing the display device 2 will be described with reference to FIGS. 23A, 23B, and 23C.

First, the above-mentioned Step-200 to Step-220 are performed. Then, for example, by performing oblique vapor deposition, an inorganic film is formed not only on the upper surface of the joint portion 280A but also on the upper surface of the light guide portion 280 (see FIG. 23A). In addition, an inorganic film is also formed in the portion of the transparent substrate 90 corresponding to the joint portion 280A and the region surrounded thereby (see FIG. 23B). Then, the display device 2 can be obtained by performing the above-mentioned Step-230 and Step-240 (see FIG. 23C).

The outline of the method for manufacturing the display device 2 has been explained above.

The second embodiment can also be modified in various ways. Hereinafter, a modification example will be described with reference to the drawings.

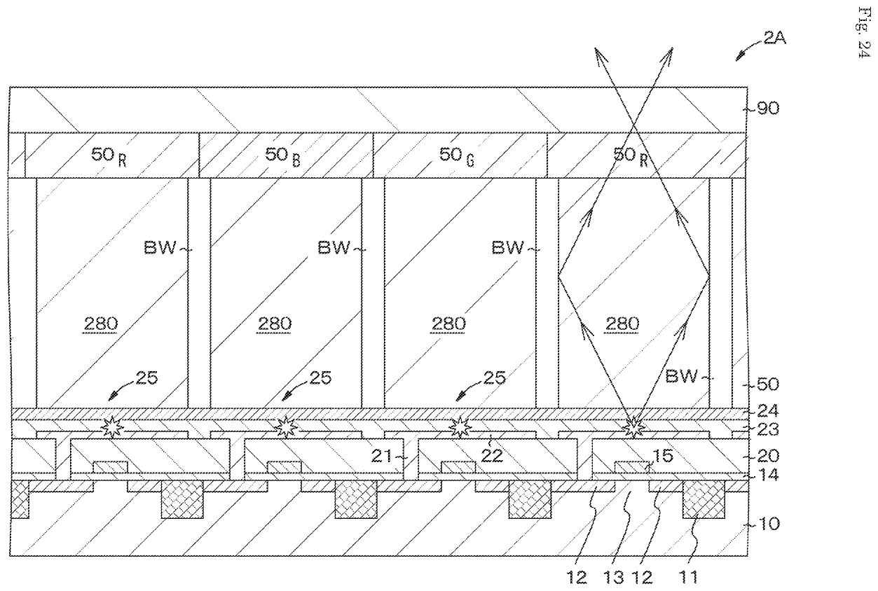

FIG. 24 is a schematic partial cross-sectional view of the display device according to the first modification example of the second aspect.

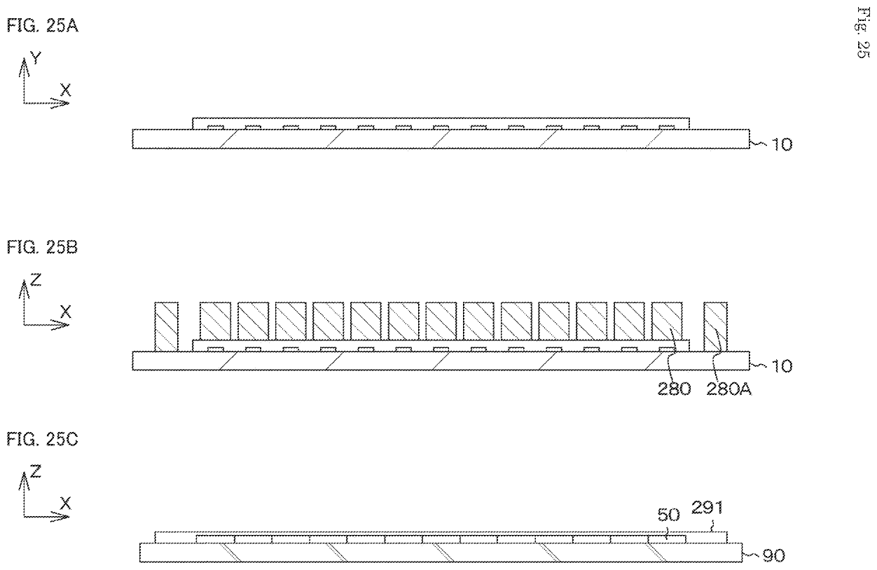

A display device 2A according to the second modification example has a configuration in which a color filter is arranged between the light guide portions and the transparent substrate. The outline of the method for manufacturing the display device 2A will be described hereinbelow with reference to FIGS. 25A, 25B, 25C. 26A. 26B. and 26C.

[Step-200A]

First, a drive circuit for the light emitting units 25, the light emitting units 25, and the like are formed on the substrate 10 (see FIG. 25A). Next, the above-mentioned Step-220 is performed to form the light guide portions 280 and the joint portion 280A (see FIG. 25B).

[Step-210A]

Further, the color filter 50 is formed on the transparent substrate 90 (see FIG. 25C). If necessary, a protective layer 291 is formed so as to cover the color filter 50. In FIG. 24, the protective layer 291 is not shown.

[Step-220A]

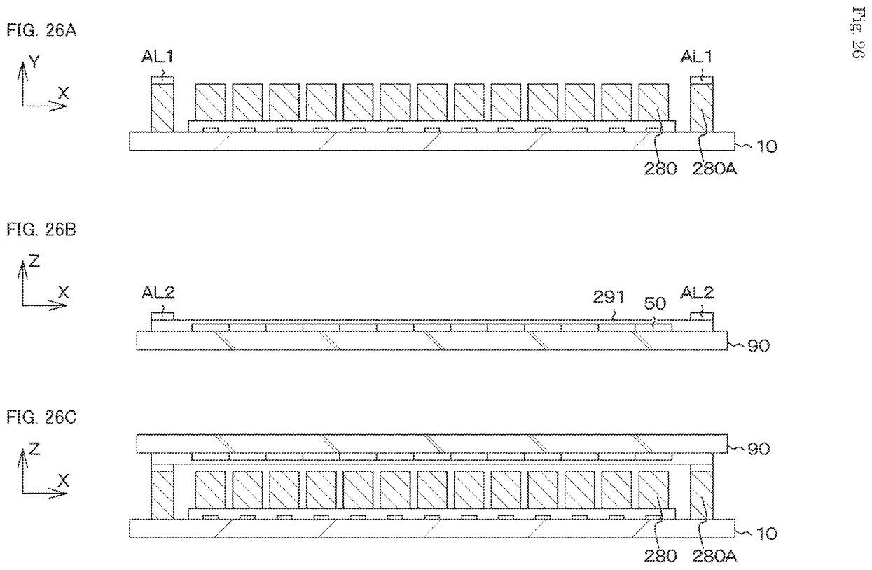

By performing the above-mentioned Step-220, an inorganic film AL1 is formed on the upper surface of the joint portion 280A provided on the substrate 10 (see FIG. 26A). and an inorganic film AL2 is formed on the portion of the transparent substrate 90 corresponding to the joint portion 280A (see FIG. 26B).

[Step-230A]

The display device 2A can be obtained by performing the above-mentioned Step-230 and Step-240 (see FIG. 26C).

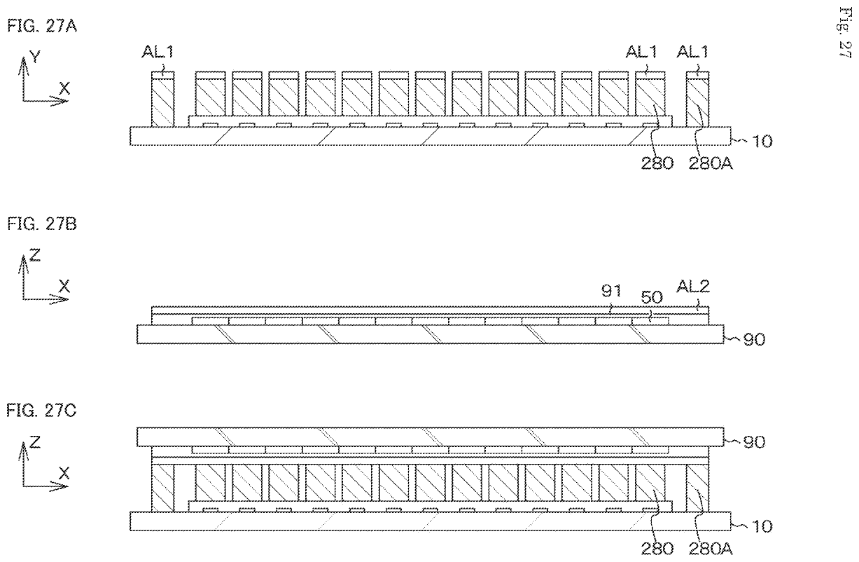

The display device 2A can also be configured by forming an inorganic film not only on the upper surface of the joint portion but also on the upper surface of the light guide portions by performing, for example, oblique vapor deposition. The outline of the method for manufacturing the display device 2A will be described hereinbelow with reference to FIGS. 27A, 27B, and 27C.

First, the above-mentioned Step-200A and Step-210A are performed. Then, by performing, for example, oblique vapor deposition, an inorganic film is formed not only on the upper surface of the joint portion 280A but also on the upper surface of the light guide portions 280 (see FIG. 27A). Further, in addition to the portion of the transparent substrate 90 corresponding to the joint portion 280A. an inorganic film is formed in the region surrounded thereby (see FIG. 27B). The display device 2A can be obtained by performing the above-mentioned Step-230 and Step-240 (see FIG. 27C).

### Third Embodiment

The third embodiment relates to a display device according to the second aspect of the present disclosure.

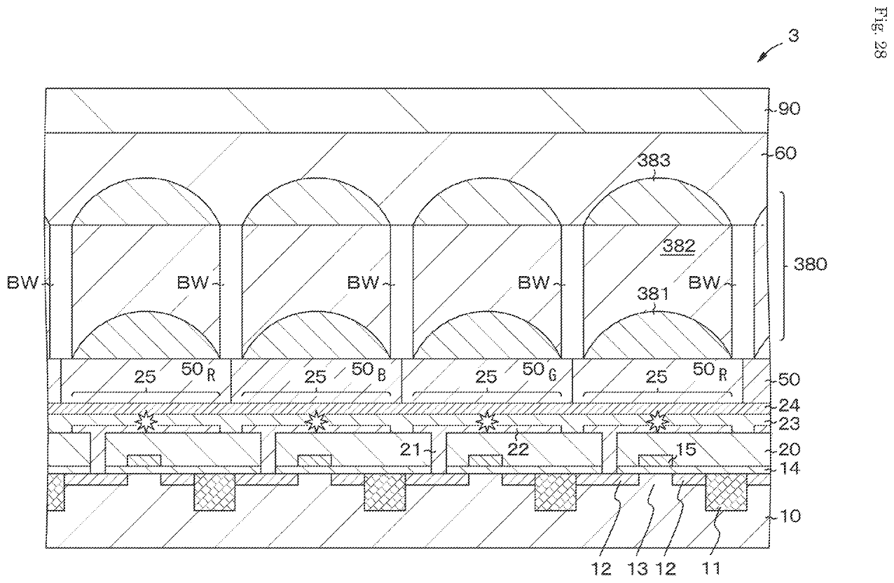

FIG. 28 is a schematic partial cross-sectional view of the display device according to the third aspect. In the schematic plan view of the display device according to the third aspect, in FIG. 17A referred to in the second embodiment, the light guide portion 280 may be read as the light guide portion 380, and the joint portion 280A may be read as the joint portion 80.

As shown in FIG. 28, the display device 3 includes columnar light guide portions 380 that are arranged above the plurality of light emitting units 25 and correspond to each light emitting unit 25. A partition wall portion BW is provided between the light guide portions 380 adjacent to each other. Similar to the display device 9 of the reference example shown in FIG. 6 referred to in the first embodiment, the color filter 50 is formed adjacent to the light emitting unit 25, and the light guide portion 380 is arranged on the color filter 50. The configuration of the substrate 10 to the color filter 50 is the same as the configuration described in the first embodiment, and thus the description thereof will be omitted.

The light guide portion 380 at least includes a first microlens 381 located above the light emitting unit 25 and a second microlens located above the first microlens 381. The partition wall portion BW is embedded in a packing layer 382 provided between the first microlens 381 and the second microlens 383, and is provided so that the refractive index thereof is smaller than that of the packing layer 382.

A configuration can be obtained in which the color filter 50 is arranged between the light emitting unit 25 and the first microlens 381, between the first microlens 381 and the second microlens 383, and above the second microlens 383. In the example shown in FIG. 28, the color filter 50 is arranged between the light emitting unit 25 and the first microlens 381.

Similar to the second embodiment, the display device 3 can also be configured such that the boundary surface between the partition wall portion and the light guide portion forms a light reflecting surface. The reflection may be a so-called total reflection or a specular reflection. In the case of total reflection, the partition wall portion may be formed as a space or may be formed of a dielectric material having a low refractive index. In the case of specular reflection, the partition wall portion can be made of a metal material having a large light reflectance such as aluminum.

In the third embodiment, the advantages of the first embodiment, such as using the first microlens 381 and the second microlens 383, and the advantages of the second embodiment such as reflection of light at the boundary surface between the partition wall portion and the light guide portion can be obtained in combination.

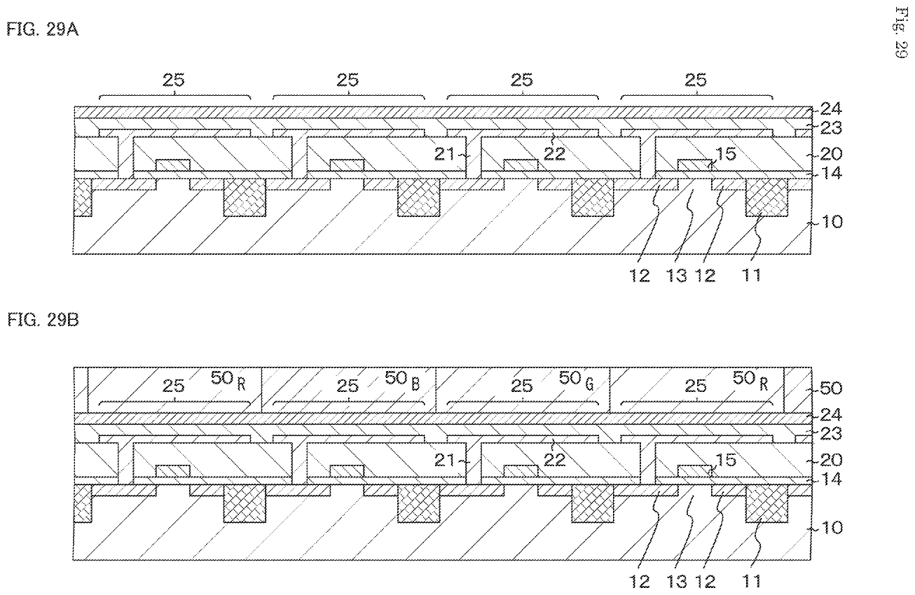

The outline of the method for manufacturing the display device 3 will be described hereinbelow with reference to FIGS. 29A, 29B, 30, 31, 32, 33, 34, 35, 36, 37, and 38 which are schematic partial end views of the substrate and the like.

[Step-300]

Step-100 to Step-120 described in the first embodiment are performed to obtain the substrate 10 on which the light emitting units 25 are formed (see FIG. 29A). After that, the color filter 50 is formed on the substrate 10 (see FIG. 29B).

[Step-310]

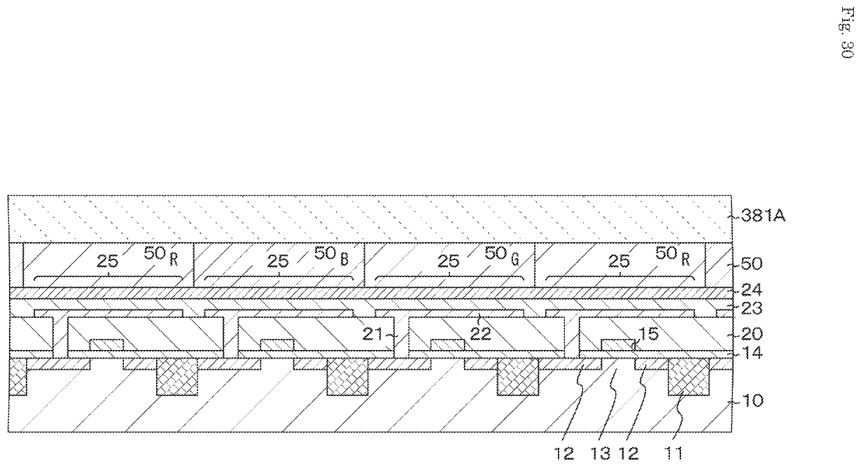

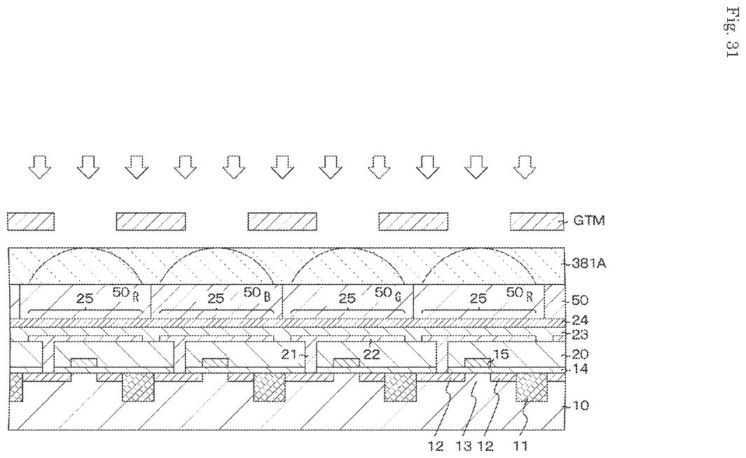

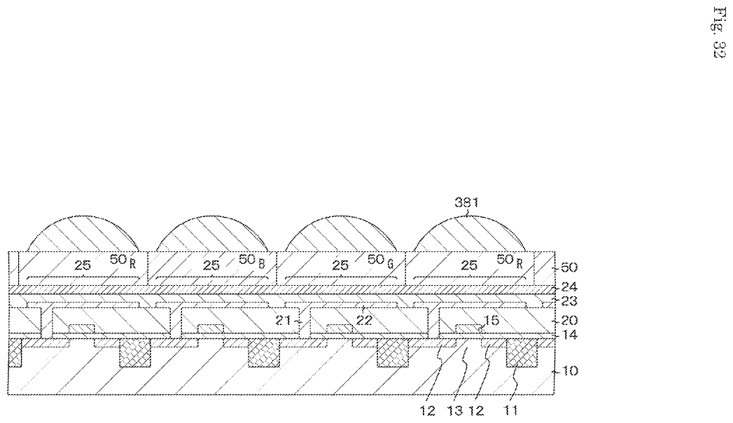

Next, a material layer 381A for configuring the first microlenses 381 is formed on the entire surface (see FIG. 30), and exposure is performed via a gray tone mask GTM (see FIG. 31). Then, development is performed to obtain first microlenses 381 (see FIG. 32).

[Step-320]

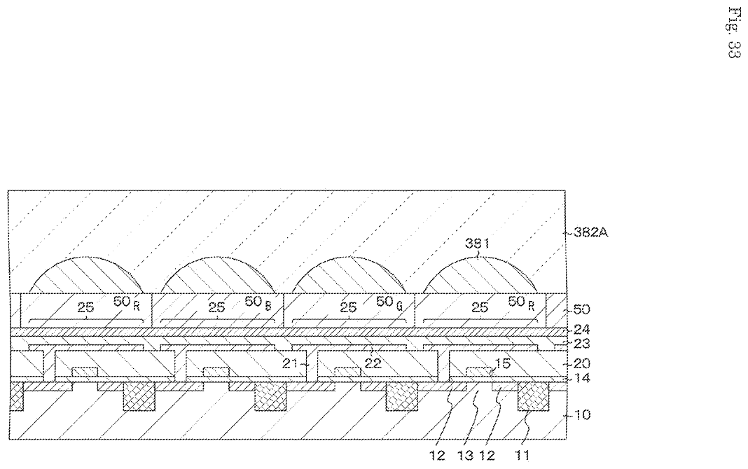

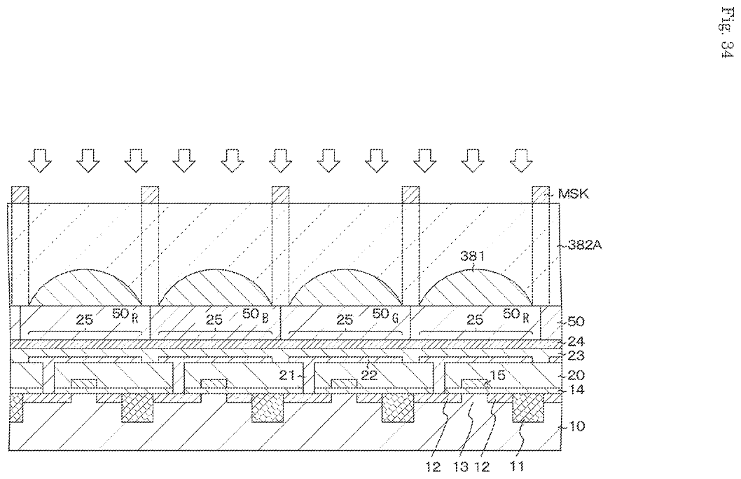

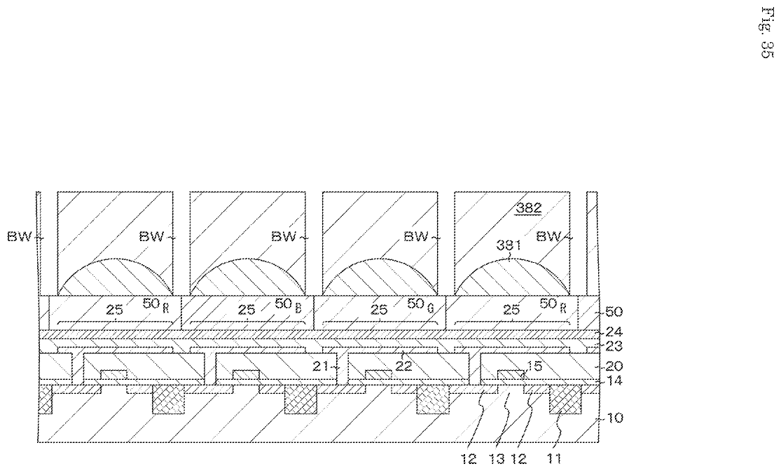

Next, a packing material layer 382A for forming the light guide portions 380 and the partition wall portions BW is formed on the entire surface (see FIG. 33), and the exposure is performed through the mask MSK in which the portions corresponding to the light guide portions 380 are opened (see FIG. 34). After that, development is performed to obtain a packing layer 382 and partition wall portions BW (see FIG. 35). Here, the partition wall portion BW is described as a space, but when the partition wall portion BW is configured of a dielectric material or a metal material, these materials may be embedded in the partition wall portion BW formed as a space.

[Step-330]

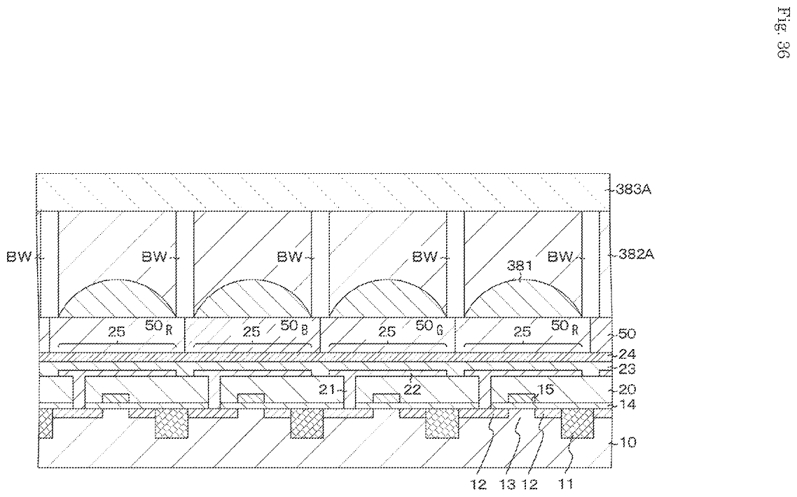

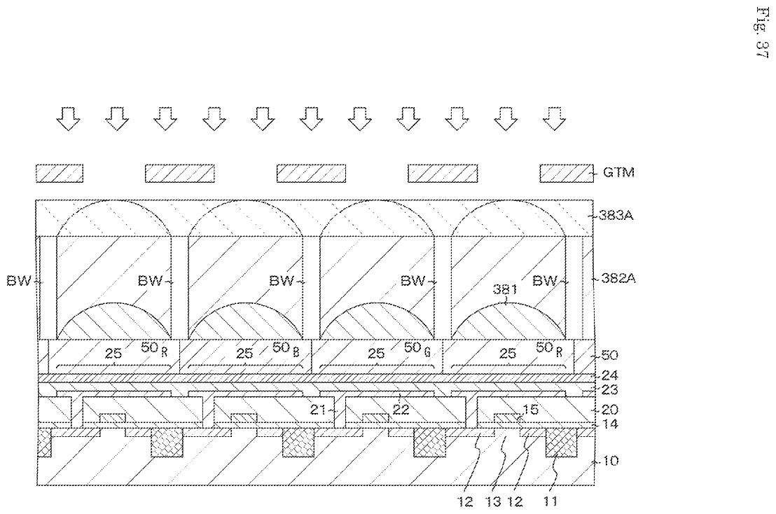

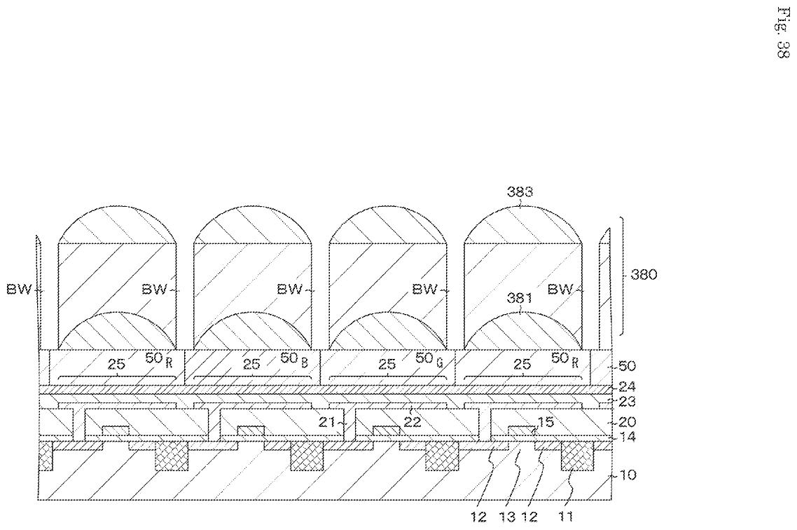

Next, a material layer 383A for configuring the second microlenses 383 is formed on the entire surface (see FIG. 36), and exposure is performed via a gray tone mask GTM (see FIG. 37). Then, development is performed to obtain second microlenses 383 (see FIG. 38).

[Step-340]

Next, the display device 3 can be obtained by bonding the substrate 10 and the transparent substrate 90 together through the sealing resin layer 60.

The outline of the method for manufacturing the display device 3 has been explained above.

Various modifications are possible also for the third embodiment. Hereinafter, a modification example will be described with reference to the drawings.

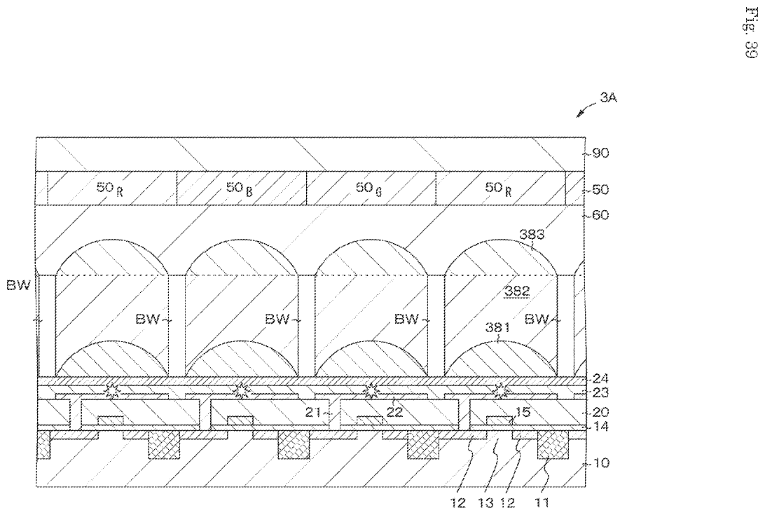

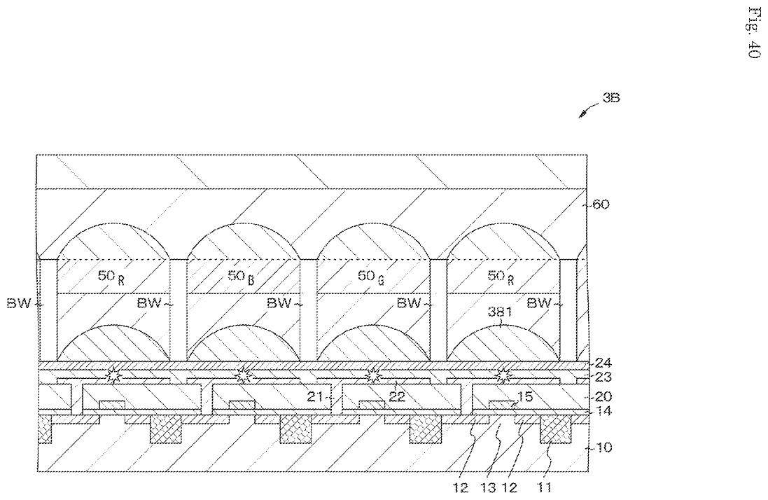

FIG. 39 is a schematic partial cross-sectional view of a display device according to the first modification example of the third embodiment. FIG. 40 is a schematic partial cross-sectional view of a display device according to the second modification example of the third embodiment.

As described above, in the third embodiment, a configuration can be obtained in which the color filter 50 is arranged between the light emitting unit 25 and the first microlens 381, between the first microlens 381 and the second microlens 383, or above the second microlens 383. In the display device 3A shown in FIG. 39, the color filter 50 is arranged between the second microlens 383 and the transparent substrate 90. Further, in the display device 3B shown in FIG. 40, the color filter 50 is arranged between the first microlens 381 and the second microlens 383.

As described in the first embodiment, qualitatively, it is preferable that the distance between the light emitting unit 25 and the first microlens 381 be small. In the display device 3 shown in FIG. 28, the chromaticity viewing angle is improved, but the light extraction efficiency is slightly lowered. In the first modification example and the second modification example, the light extraction efficiency can be improved as compared with the configuration shown in FIG. 28. In the first modification example, the chromaticity viewing angle is slightly reduced. Meanwhile, the second modification example has an advantage that both the light extraction efficiency and the chromaticity viewing angle can be improved.

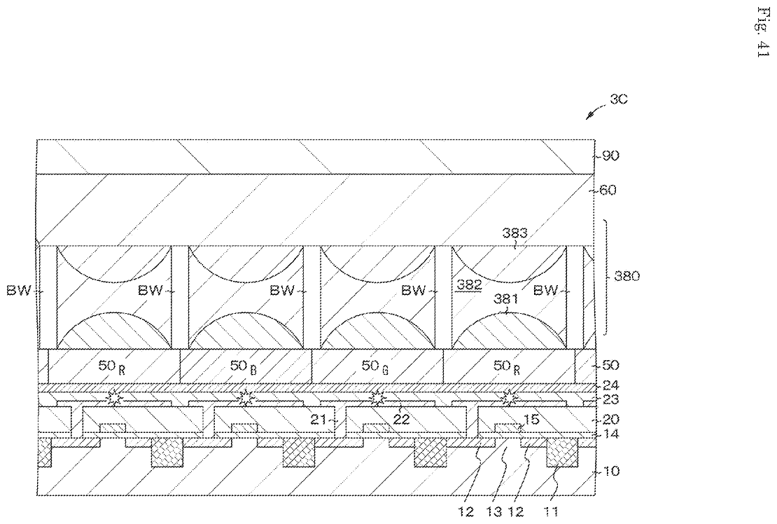

FIG. 41 is a schematic partial cross-sectional view of the display device according to the third modification example of the third embodiment.

In the display device 3C shown in FIG. 41, the second microlens 383 is of a concave lens type. When the second microlens 383 is a convex lens, qualitatively, the front luminance tends to be higher than the peripheral luminance. For example, in the case of an application in which luminance is also required on the wide viewing angle side, it is possible to control the light beam to diverge toward the wide viewing angle side of the panel by making the second microlens 383 a concave lens.

[Electronic Devices]

The display device of the present disclosure described above can be used as a display unit (display device) of an electronic device in all fields for displaying a video signal input to an electronic device or a video signal generated in the electronic device as an image or a video. As an example, the display device can be used as a display unit such as a television set, a digital still camera, a notebook personal computer, a mobile terminal device such as a mobile phone, a video camera, and a head-mounted display (head-mounted display unit).

The display device of the present disclosure is also inclusive of a modular device having a sealed configuration. Such device can be exemplified by a display module formed by attaching a facing portion such as transparent glass to a pixel array portion. The display module may be provided with a circuit unit, a flexible printed circuit (FPC), or the like for inputting/outputting a signal or the like from the outside to the pixel array unit. Hereinafter, a digital still camera and a head-mounted display will be illustrated as specific examples of the electronic device using the display device of the present disclosure. However, the specific examples illustrated herein are only examples, and are not limiting.

### Specific Example 1

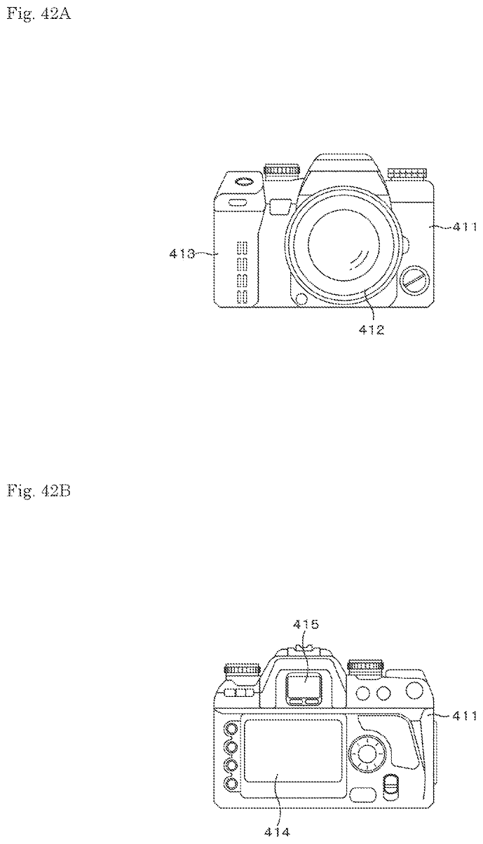

FIG. 42 is an external view of an interchangeable-lens single-lens reflex type digital still camera, the front view thereof is shown in FIG. 42A, and the rear view thereof is shown in FIG. 42B. The interchangeable-lens single-lens reflex type digital still camera has, for example, an interchangeable image capturing lens unit (interchangeable lens) 412 on the front right side of a camera main body (camera body) 411, and has a grip portion 413 on the front left side to be held by a photographer.

A monitor 414 is provided in a substantially center portion of the back surface of the camera main body 411. A viewfinder (eyepiece window) 415 is provided above the monitor 414. By looking into the viewfinder 415, the photographer can visually recognize the light image of the subject introduced from the image capturing lens unit 412 and determine the composition.

The display device of the present disclosure can be used as the viewfinder 415 in the interchangeable-lens single-lens reflex type digital still camera having the above-described configuration. That is, the interchangeable-lens type single-lens reflex type digital still camera according to the present example can be produced by using the display device of the present disclosure as the viewfinder 415 thereof.

### Specific Example 2

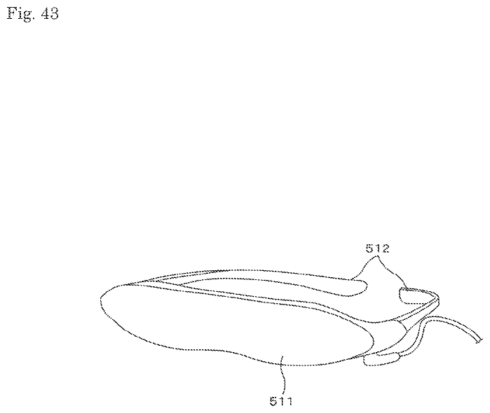

FIG. 43 is an external view of the head-mounted display. The head-mounted display has, for example, ear hook portions 512 enabling wearing on the user's head on both sides of an eyeglass-shaped display unit 511. In this head-mounted display, the display device of the present disclosure can be used as the display unit 511. That is, the head-mounted display according to the present example can be manufactured by using the display device of the present disclosure as the display unit 511.

### Specific Example 3

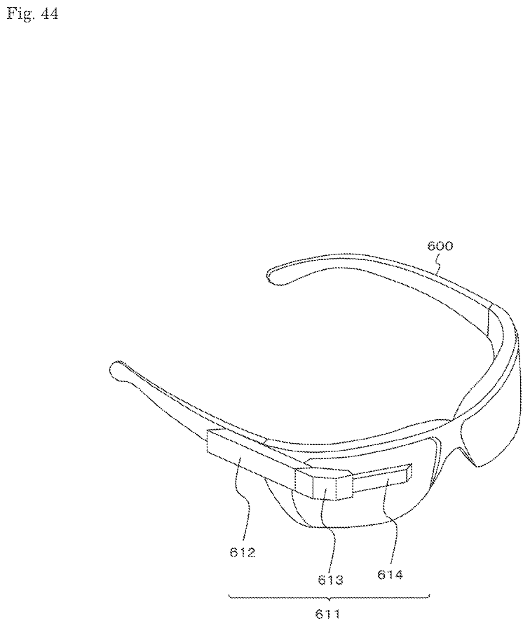

FIG. 44 is an external view of a see-through head-mounted display. The see-through head-mounted display 611 is configured of a main body 612, an arm 613, and a lens barrel 614.

The main body 612 is connected to the arm 613 and eyeglasses 600. Specifically, the end of the main body 612 in the long side direction is joined to the arm 613, and one side of the side surface of the main body 612 is coupled to the eyeglasses 600 via a connecting member. The main body 612 may be directly attached to the head of the human body.

The main body 612 incorporates a control board for controlling the operation of the see-through head-mounted display 611, and a display unit. The arm 613 connects the main body 612 and the lens barrel 614, and supports the lens barrel 614. Specifically, the arm 613 is joined to the end of the main body 612 and the end of the lens barrel 614, respectively, to fix the lens barrel 614. Further, the arm 613 incorporates a signal line for communicating data related to an image provided from the main body 612 to the lens barrel 614.

The lens barrel 614 projects the image light provided from the main body 612 via the arm 613 toward the eyes of the user who wears the see-through head-mounted display 611 through an eyepiece. In this see-through head-mounted display 611, the display device of the present disclosure can be used for the display unit of the main body 612.

[Other]

The art of the present disclosure can also have the following configurations.

[A1]

A display device at least including:

a plurality of light emitting units arranged in a two-dimensional matrix on a substrate;

a first lens unit that is arranged above the plurality of light emitting units and has first microlenses corresponding to each light emitting unit; and

a second lens unit that is arranged above the first lens unit and has second microlenses corresponding to each light emitting unit.

[A2]

The display device according to A1, wherein

a color filter is arranged between the first microlens and the second microlens.

[A3]

The display device according to A1, further including

a third lens unit that is arranged above the second lens unit and has third microlenses corresponding to each light emitting unit.

[A4]

The display device according to A3, wherein

color filters are respectively arranged between the first microlens and the second microlens, and between the second microlens and the third microlens.

[A5]

The display device according to any one of A1 to A4, wherein

a refractive index of a material forming the first microlens is larger than a refractive index of a material forming the second microlens.

[A6]

The display device according to A5, wherein

a color filter is arranged between the first microlens and the second microlens, and

a refractive index of an optical material forming the color filter is smaller than a refractive index of an optical material forming the first microlens and equal to or higher than a refractive index of an optical material forming the second microlens.

[A7]

The display device according to A5 or A6, wherein

the first microlens is formed of an inorganic material, and the second microlens is formed of an organic material.

[B1]

A display device including:

a plurality of light emitting units arranged in a two-dimensional matrix on a substrate; and

columnar light guide portions that are arranged above the plurality of light emitting units and correspond to each light emitting unit, wherein

a partition wall portion is provided between the light guide portions adjacent to each other.

[B2]

The display device according to B1, wherein

a boundary surface between the partition wall portion and the light guide portion forms a light reflecting surface.

[B3]

The display device according to B1 or B2, wherein

the light guide portion is formed of a dielectric material,

[B4]

The display device according to B3, wherein

the light guide portion is made of an organic material.

[B5]

The display device according to any one of B1 to B4, wherein

the partition wall portion is provided so that a refractive index thereof is smaller than that of the light guide portion.

[B6]

The display device according to any one of B1 to B5, wherein

the partition wall portion is formed as a space.

[B7]

The display device according to any one of B1 to B6, wherein

the partition wall portion is formed of a dielectric material,

[B8]

The display device according to B1, wherein

the partition wall portion is formed of a metal material.

[B9]

The display device according to any one of B1 to B8, wherein

a boundary surface between the partition wall portion and the light guide portion extends in a normal direction of a virtual plane including the plurality of light emitting units.

[B10]

The display device according to any one of B1 to B8, wherein

a boundary surface between the partition wall portion and the light guide portion extends so as to form a predetermined angle with respect to the normal direction of the virtual plane including the plurality of light emitting units.

[B11]

The display device according to any one of B1 to B10, including

a transparent substrate arranged so as to face the substrate, wherein

the substrate is provided with a joint portion arranged so as to surround the region of the plurality of light emitting units arranged in a two-dimensional matrix, and

the substrate and the transparent substrate are joined through the joint portion.

[B12]

The display device according to B11, wherein

a height of the joint is formed to be an equal height to the light guide portion.

[B13]

The display device according to any one of B1 to B12, wherein

the light guide portion at least includes a first microlens located above the light emitting unit and a second microlens located above the first microlens.

[B14]

The display device according to B13, wherein

the partition wall portion is embedded in a packing layer provided between the first microlens and the second microlens, and is provided so that a refractive index thereof is smaller than that of the packing layer.

[B15]

The display device according to B13, wherein

a color filter is arranged between the light emitting unit and the first microlens, between the first microlens and the second microlens, or above the second microlens.

### REFERENCE SIGNS LIST

1 1A 1B 1C 2 2A 3 3A 3B 3C 9 Display device
10 Substrate
11 Element separation region
12 Source/drain region
13 Channel region
14 Gate insulating layer
15 Gate electrode
20 Flattening film
21 Contact plug
22 Anode electrode
23 Organic layer
24 Cathode electrode
25 Light emitting unit
30A First lens unit
30B Second lens unit
30C Third lens unit
31A First microlens
31B Second microlens
31C Third microlens
40 Flattening film
50, 50_{R}, 50_{G}, 50_{B}, 50A, 50A_{R}, 50A_{G}, 50A_{B} Color filter
60 Sealing resin layer
70, 70_{R}, 70_{G}, 70_{B} Pixel
80 Joint portion
90 Transparent substrate
280 Light guide portion
280A Joint portion
380 Light guide portion
381 First microlens
381A Material layer for forming first microlens
382 Packing layer
382A Packing material layer
383 Second microlens
383A Material layer for forming second microlens
BW Partition wall portion
AL1, AL2 Inorganic film
411 Camera main body
412 Image capturing lens unit
413 Grip portion
414 Monitor
415 Viewfinder
511 Eyeglasses-shaped display unit
512 Ear hook portion
600 Eyeglasses
611 See-through head mount display
612 Main body
613 Arm
614 Lens barrel

1. A display device at least comprising:
a plurality of light emitting units arranged in a two-dimensional matrix on a substrate;
a first lens unit that is arranged above the plurality of light emitting units and has first microlenses corresponding to each light emitting unit; and
a second lens unit that is arranged above the first lens unit and has second microlenses corresponding to each light emitting unit.

2. The display device according to claim 1, wherein
a color filter is arranged between the first microlens and the second microlens.

3. The display device according to claim 1, further comprising
a third lens unit that is arranged above the second lens unit and has third microlenses corresponding to each light emitting unit.

4. The display device according to claim 3, wherein
color filters are respectively arranged between the first microlens and the second microlens, and between the second microlens and the third microlens.

5. The display device according to claim 1, wherein
a refractive index of a material forming the first microlens is larger than a refractive index of a material forming the second microlens.

6. The display device according to claim 5, wherein
a color filter is arranged between the first microlens and the second microlens, and
a refractive index of an optical material forming the color filter is smaller than a refractive index of an optical material forming the first microlens and equal to or higher than a refractive index of an optical material forming the second microlens.

7. The display device according to claim 5, wherein
the first microlens is formed of an inorganic material, and the second microlens is formed of an organic material.

8. A display device comprising:
a plurality of light emitting units arranged in a two-dimensional matrix on a substrate; and
columnar light guide portions that are arranged above the plurality of light emitting units and correspond to each light emitting unit, wherein
a partition wall portion is provided between the light guide portions adjacent to each other.

9. The display device according to claim 8, wherein
a boundary surface between the partition wall portion and the light guide portion forms a light reflecting surface.

10. The display device according to claim 8, wherein
the light guide portion is formed of a dielectric material.

11. The display device according to claim 10, wherein
the light guide portion is made of an organic material.

12. The display device according to claim 8, wherein
the partition wall portion is provided so that a refractive index thereof is smaller than that of the light guide portion.

13. The display device according to claim 8, wherein
the partition wall portion is formed as a space.

14. The display device according to claim 8, wherein
the partition wall portion is formed of a dielectric material.

15. The display device according to claim 8, wherein
the partition wall portion is formed of a metal material.

16. The display device according to claim 8, wherein
a boundary surface between the partition wall portion and the light guide portion extends in the normal direction of a virtual plane including the plurality of light emitting units.

17. The display device according to claim 8, wherein
a boundary surface between the partition wall portion and the light guide portion extends so as to form a predetermined angle with respect to a normal direction of a virtual plane including the plurality of light emitting units.

18. The display device according to claim 8, comprising
a transparent substrate arranged so as to face the substrate, wherein the substrate is provided with a joint portion arranged so as to surround the region of the plurality of light emitting units arranged in a two-dimensional matrix, and
the substrate and the transparent substrate are joined through the joint portion.

19. The display device according to claim 18, wherein
a height of the joint is formed to be an equal height to the light guide portion.

20. The display device according to claim 8, wherein
the light guide portion at least includes a first microlens located above the light emitting unit and a second microlens located above the first microlens.

21. The display device according to claim 20, wherein
the partition wall portion is embedded in a packing layer provided between the first microlens and the second microlens, and is provided so that a refractive index thereof is smaller than that of the packing layer.

22. The display device according to claim 20, wherein
a color filter is arranged at either of positions between the light emitting unit and the first microlens, between the first microlens and the second microlens, or above the second microlens.
